(19) United States
(12) Patent Application Publication
(10) Pub. No.: US 2025/0386571 A1
(43) Pub. Date: Dec. 18, 2025

(54) TRANSISTOR CHANNEL STRUCTURES COMBINING GALLIUM NITRIDE AND SILICON CARBIDE

(71) Applicant: Intel Corporation, Santa Clara, CA (US)

(72) Inventors: Abhishek A. Sharma, Portland, OR (US); Han Wui Then, Portland, OR (US); Anand S. Murthy, Portland, OR (US); Tahir Ghani, Portland, OR (US); Wilfred Gomes, Portland, OR (US)

(73) Assignee: Intel Corporation, Santa Clara, CA (US)

(21) Appl. No.: 18/740,743

(22) Filed: Jun. 12, 2024

(51) Int. Cl. H01L 29/267; H01L 29/06; H01L 29/10; H01L 29/16; H01L 29/20; H01L 29/423; H01L 29/775; H01L 29/78; H01L 29/786

(52) U.S. Cl. CPC H10D 62/82; H10D 30/43; H10D 30/62; H10D 30/6735; H10D 30/6741; H10D 30/675; H10D 30/6757; H10D 30/751; H10D 62/121; H10D 62/8325; H10D 62/8503

(57) ABSTRACT

Disclosed herein are transistor channel structures combining GaN and SiC, and related IC structures, devices, and techniques. For example, in some embodiments, a transistor may include a gate electrode material; a gate insulator material; and a channel structure, wherein the gate insulator material is between the channel structure and the gate electrode material, the channel structure includes a first portion, a second portion, and a third portion, and the second portion is between the first portion and the third portion, and wherein either (1) the first portion and the third portion include gallium and nitrogen, and the second portion includes silicon and carbon, or (2) the first portion and the third portion include silicon and carbon, and the second portion includes gallium and nitrogen.

### BACKGROUND

For the past several decades, the scaling of features in integrated circuit (IC) structures has been a driving force behind an ever-growing semiconductor industry. Scaling to smaller and smaller features enables increased densities of functional units on the limited real estate of semiconductor chips. For example, shrinking transistor size allows for the incorporation of an increased number of memory or logic devices on a chip, lending to the fabrication of products with increased capacity. The drive for the ever-increasing capacity, however, is not without issue. The necessity to optimize every portion of an IC structure becomes increasingly significant. One area for optimization is carefully selecting channel materials of transistors included in IC structures to achieve optimal performance.

### BRIEF DESCRIPTION OF THE DRAWINGS

Embodiments will be readily understood by the following detailed description in conjunction with the accompanying drawings. To facilitate this description, like reference numerals designate like structural elements. Embodiments are illustrated by way of example, and not by way of limitation, in the figures of the accompanying drawings.

FIG. 1 is a cross-sectional side view of a transistor gate-channel arrangement including a channel structure combining gallium nitride (GaN) and silicon carbide (SIC), in accordance with various embodiments.

FIGS. 2-6 are cross-sectional side views of example single-gate transistors including a channel structure combining GaN and SiC, in accordance with various embodiments.

FIGS. 7-9 are cross-sectional side views of example double-gate transistors including a channel structure combining GaN and SiC, in accordance with various embodiments.

FIGS. 10A and 10B are perspective and cross-sectional side views, respectively, of an example tri-gate transistor including a channel structure combining GaN and SiC, in accordance with various embodiments.

FIGS. 11A and 11B are perspective and cross-sectional side views, respectively, of an example all-around gate transistor including a channel structure combining GaN and SiC, in accordance with various embodiments.

FIGS. 12A-12C are cross-sectional side views of channel structures combining portions of GaN and SiC stacked above one another, in accordance with various embodiments.

FIGS. 13A-13F are cross-sectional side views of channel structures combining portions of GaN and SiC arranged sequentially along the gate length of a transistor, in accordance with various embodiments.

FIG. 14 illustrates top views of a wafer and dies that may include one or more integrated circuit (IC) structures with transistor channel structures combining GaN and SiC, in accordance with various embodiments.

FIG. 15 is a side, cross-sectional view of an IC device that may include one or more IC structures with transistor channel structures combining GaN and SiC, in accordance with various embodiments.

FIG. 16 is a side, cross-sectional view of an IC package that may include one or more IC structures with transistor channel structures combining GaN and SiC, in accordance with various embodiments.

FIG. 17 illustrates a cross-sectional side view of an IC device assembly that may include one or more IC structures with transistor channel structures combining GaN and SiC, in accordance with various embodiments.

FIG. 18 is a block diagram of an example computing device that may include one or more IC structures with transistor channel structures combining GaN and SiC, in accordance with various embodiments.

FIG. 19 is a block diagram of an example processing device that may include one or more IC structures with transistor channel structures combining GaN and SiC, in accordance with various embodiments.

### DETAILED DESCRIPTION

Disclosed herein are transistor channel structures combining GaN and SiC, and related IC structures, devices, and techniques. Although many descriptions are provided herein with reference to GaN and SiC, these descriptions are applicable to any embodiments where some portions of transistor channel structures include semiconductor materials comprising gallium and nitrogen in any form other than GaN and where other portions of transistor channel structures include semiconductor materials comprising silicon and carbon in any form other than SiC. For example, in some embodiments, a transistor may include a gate electrode material; a gate insulator material; and a channel structure, wherein the gate insulator material is between the channel structure and the gate electrode material, the channel structure includes a first portion, a second portion, and a third portion, and the second portion is between the first portion and the third portion, and wherein either (1) the first portion and the third portion include gallium and nitrogen (e.g., in the form of GaN), and the second portion includes silicon and carbon (e.g., in the form of SiC), or (2) the first portion and the third portion include silicon and carbon (e.g., in the form of SiC), and the second portion includes gallium and nitrogen (e.g., in the form of GaN). Including both, portions comprising GaN and portions comprising SiC, in a channel structure of a transistor may help optimize performance of the transistor in terms of one or more competing parameters, e.g., a breakdown voltage of the transistor.

Breakdown voltage is the maximum voltage that a transistor can withstand before it undergoes irreversible damage or enters a destructive breakdown state. It is a critical parameter in defining the safe operating limits of the transistor. Performance of a transistor typically refers to parameters such as current gain (e.g., the amplification capability of the transistor), switching speed (e.g., the speed at which the transistor can turn on and off, which is crucial in high-frequency applications), on-resistance (e.g., the resistance between the drain and source in a transistor when it is in the on state, impacting efficiency and heat dissipation), or power handling capability (e.g., the ability of the transistor to handle power without excessive heating or failure). High breakdown voltage transistors typically require thicker and higher-resistivity materials to withstand higher voltages. These materials can reduce the mobility of charge carriers (electrons and holes), leading to slower switching speeds and lower current gain, thus reducing performance of transistors. Thicker depletion regions required for high breakdown voltage also result in increased capacitance, which adversely affects the high-frequency performance. GaN is an example of a semiconductor material associated with a relatively high performance but only moderate breakdown voltage. On the other hand, SiC is an example of a semiconductor material associated with a relatively high breakdown voltage but only moderate performance. In conventional transistor design, engineers balance these factors and choose either GaN or SiC as a transistor channel material. For example, power transistors used in high-voltage power supplies or motor control systems may prioritize high breakdown voltage over switching speed and, therefore, use SiC as their channel materials. On the other hand, transistors in radio frequency (RF) applications may prioritize switching speed and high-frequency performance, often at the cost of reduced breakdown voltage, and therefore use GaN as their channel materials. In contrast to such conventional implementations, channel materials of transistors described herein include both, portions comprising GaN and portions comprising SiC (therefore, instead of using the term “channel material” the term “channel structure” is used), where dimensions and arrangements of these portions within a channel structure may be individually controlled to achieve desired tradeoff between transistor performance and transistor parameters such as breakdown voltage.

In the following detailed description, various aspects of the illustrative implementations may be described using terms commonly employed by those skilled in the art to convey the substance of their work to others skilled in the art. For example, the term “connected” means a direct electrical connection between the things that are connected (e.g., with the things being in electrically conductive and/or physical contact with), without any intermediary devices, while the term “coupled” means either a direct electrical connection between the things that are connected, or an indirect connection through one or more passive or active intermediary devices. Describing A and B are being “in contact” includes A and B being in direct physical contact, possibly with an interface that may form when A and B are brough into direct physical contact with one another. The term “circuit” means one or more passive and/or active components that are arranged to cooperate with one another to provide a desired function. The terms “oxide,” “carbide,” “nitride,” etc. refer to compounds containing, respectively, oxygen, carbon, nitrogen, etc., the term “high-k dielectric” refers to a material having a higher dielectric constant (k) than silicon oxide, while the term “low-k dielectric” refers to a material having a lower k than silicon oxide. The terms “substantially,” “close,” “approximately,” “near,” and “about,” generally refer to being within +/−20%, e.g., within +/−5% or within +/−2%, of a target value based on the context of a particular value as described herein or as known in the art. Similarly, terms indicating orientation of various elements, e.g., “coplanar,” “perpendicular,” “orthogonal,” “parallel,” or any other angle between the elements, generally refer to being within +/−20%, e.g., within +/−5% or within +/−2% of a target value based on the context of a particular value as described herein or as known in the art.

The terms “over,” “under,” “between,” and “on” as used herein refer to a relative position of one material layer or component with respect to other layers or components. For example, one layer disposed over or under another layer may be directly in contact with the other layer or may have one or more intervening layers. Moreover, one layer disposed between two layers may be directly in contact with the two layers or may have one or more intervening layers. In contrast, a first layer “on” a second layer is in direct contact with that second layer. Similarly, unless explicitly stated otherwise, one feature disposed between two features may be in direct contact with the adjacent features or may have one or more intervening layers.

For the purposes of the present disclosure, the phrase “A and/or B” means (A), (B), or (A and B). For the purposes of the present disclosure, the phrase “A, B, and/or C” means (A), (B), (C), (A and B), (A and C), (B and C), or (A, B, and C). The term “between,” when used with reference to measurement ranges, is inclusive of the ends of the measurement ranges. As used herein, the notation “A/B/C” means (A), (B), and/or (C).

Although certain elements may be referred to in the singular herein, such elements may include multiple sub-elements. For example, “an insulator material” may include one or more insulator materials. The term “insulating” and variations thereof (e.g., “insulative” or “insulator”) means “electrically insulating,” the term “conducting” and variations thereof (e.g., “conductive” or “conductor”) means “electrically conducting,” unless otherwise specified. For example, the term “insulator material” may refer to solid materials (and/or liquid materials that solidify after processing as described herein) that are substantially electrically non-conducting. They may include, as examples and not as limitations, organic polymers and plastics, and inorganic materials such as ionic crystals, porcelain, glass, silicon and alumina or a combination thereof. They may include dielectric materials, high polarizability materials, and/or piezoelectric materials. They may be transparent or opaque without departing from the scope of the present disclosure. With reference to optical signals and/or devices, components and elements that operate on or using optical signals, the term “conducting/conductive” can also mean “optically conducting/conductive.”

The description may use the phrases “in an embodiment” or “in embodiments,” which may each refer to one or more of the same or different embodiments. Furthermore, the terms “comprising,” “including,” “having,” and the like, as used with respect to embodiments of the present disclosure, are synonymous. The disclosure may use perspective-based descriptions such as “above,” “below,” “top,” “bottom,” and “side”; such descriptions are used to facilitate the discussion and are not intended to restrict the application of disclosed embodiments. The accompanying drawings are not necessarily drawn to scale. Unless otherwise specified, the use of the ordinal adjectives “first,” “second,” and “third,” etc., to describe a common object, merely indicate that different instances of like objects are being referred to and are not intended to imply that the objects so described must be in a given sequence, either temporally, spatially, in ranking or in any other manner.

In the following detailed description, reference is made to the accompanying drawings that form a part hereof wherein like numerals designate like parts throughout, and in which is shown, by way of illustration, embodiments that may be practiced. It is to be understood that other embodiments may be utilized, and structural or logical changes may be made, without departing from the scope of the present disclosure. Therefore, the following detailed description is not to be taken in a limiting sense.

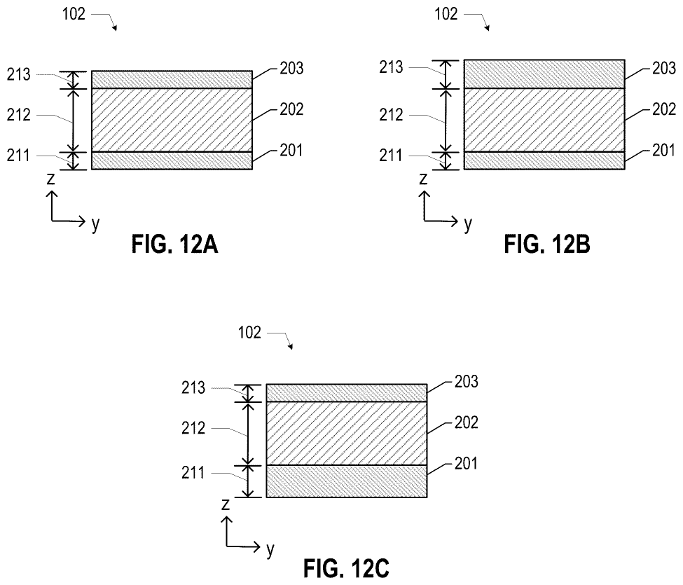

Any of the features discussed with reference to any of accompanying drawings herein may be combined with any other features to form IC structures with transistor channel structures combining GaN and SiC, as appropriate. A number of elements of the drawings are shared with others of the drawings; for ease of discussion, a description of these elements is not repeated, and these elements may take the form of any of the embodiments disclosed herein. For convenience, a collection of drawings labeled with letters may be referred to without letters (e.g., a collection of drawings shown in FIGS. 12A-12C may be referred to as FIG. 12).

The drawings are not necessarily to scale. In the drawings, some schematic illustrations of example structures of various devices and assemblies described herein may be shown with precise right angles and straight lines, but it is to be understood that such schematic illustrations may not reflect real-life process limitations which may cause the features to not look so “ideal” when any of the structures described herein are examined using e.g., scanning electron microscopy (SEM) images or transmission electron microscope (TEM) images. In such images of real structures, possible processing defects could also be visible, e.g., not-perfectly straight edges of materials, tapered vias or other openings, inadvertent rounding of corners or variations in thicknesses of different material layers, occasional screw, edge, or combination dislocations within the crystalline region, and/or occasional dislocation defects of single atoms or clusters of atoms. There may be other defects not listed here but that are common within the field of device fabrication. Inspection of layout and mask data and reverse engineering of parts of a device to reconstruct the circuit using e.g., optical microscopy, TEM, or SEM, and/or inspection of a cross-section of a device to detect the shape and the location of various device elements described herein using, e.g., Physical Failure Analysis (PFA) would allow determination of presence of IC structures with transistor channel structures combining GaN and SiC as described herein.

Various IC structures with transistor channel structures combining GaN and SiC as described herein may be implemented in, or associated with, one or more components associated with an IC or/and may be implemented between various such components. In various embodiments, components associated with an IC include, for example, transistors, diodes, power sources, resistors, capacitors, inductors, sensors, transceivers, receivers, antennas, etc. Components associated with an IC may include those that are mounted on IC or those connected to an IC. The IC may be either analog or digital and may be used in a number of applications, such as microprocessors, optoelectronics, logic blocks, audio amplifiers, etc., depending on the components associated with the IC. The IC may be employed as part of a chipset for executing one or more related functions in a computer.

FIG. 1 is a cross-sectional side view of an IC structure 100 including a channel structure 102 combining GaN and SiC, and further including a transistor gate stack 104 (also referred to as a “gate stack 104” herein), in accordance with various embodiments. The transistor gate stack 104 may include a gate electrode material 108, and a gate insulator material 106 disposed between the gate electrode material 108 and the channel structure 102.

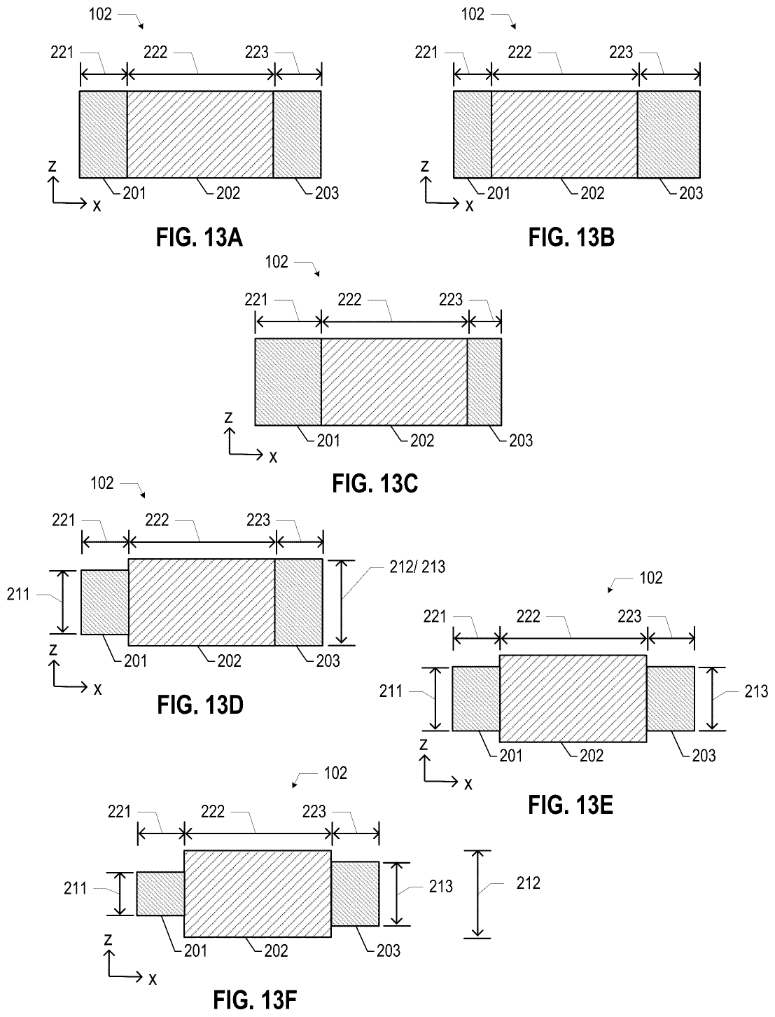

The channel structure 102 may combine one or more portions comprising gallium and nitrogen (e.g., in the form of GaN) and one or more portions comprising silicon and carbon (e.g., in the form of SiC). Details of various arrangements of the different portions of the channel structure 102 are described below with reference to FIGS. 12A-12C and FIGS. 13A-13F. Including both portions comprising GaN and portions comprising SiC in the channel structure 102 may help optimize performance of a transistor (e.g., any of the transistors 120 discussed herein) in terms of one or more competing parameters, such as breakdown voltage of a transistor (e.g., may help optimize performance of a transistor while maintaining adequate breakdown voltage). Such embodiments may combine the breakdown voltage advantages and disadvantages of the individual portions to achieve a desired overall performance.

The gate electrode material 108 may include at least one p-type work function metal or n- type work function metal, depending on whether the transistor gate stack 104 is to be included in a p-type metal oxide semiconductor (PMOS) transistor or an n-type metal oxide semiconductor (NMOS) transistor (e.g., any of the transistors 120 discussed below). For a PMOS transistor, metals that may be used for the gate electrode material 108 may include, but are not limited to, ruthenium, palladium, platinum, cobalt, nickel, and conductive metal oxides (e.g., ruthenium oxide). For an NMOS transistor, metals that may be used for the gate electrode material 108 include, but are not limited to, hafnium, zirconium, titanium, tantalum, aluminum, alloys of these metals, and carbides of these metals (e.g., hafnium carbide, zirconium carbide, titanium carbide, tantalum carbide, and aluminum carbide). In some embodiments, the gate electrode material 108 may consist of a stack of two or more metal layers, where one or more metal layers are work function metal layers and at least one metal layer is a fill metal layer. Further metal layers may be included for other purposes, such as to act as a barrier layer.

In some embodiments, the gate insulator material 106 may include a high-k dielectric. The high-k dielectric may include elements such as hafnium, silicon, oxygen, titanium, tantalum, lanthanum, aluminum, zirconium, barium, strontium, yttrium, lead, scandium, niobium, and zinc. Examples of high-k materials that may be used in the gate insulator material 106 may include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, tantalum oxide, tantalum silicon oxide, lead scandium tantalum oxide, and lead zinc niobate. In some embodiments, an annealing process may be carried out on the gate insulator material 106 during fabrication of a transistor (e.g., any of the transistors 120 discussed herein) to improve the quality of the gate insulator material 106. The gate insulator material 106 may have a thickness that may, in some embodiments, be between about 0.5 nanometers and 3 nanometers, including all values and ranges therein (e.g., between about 1 and 3 nanometers, or between about 1 and 2 nanometers). In some embodiments, the gate stack 104 may be surrounded by a gate spacer, not shown in FIG. 1. Such a gate spacer would be configured to provide separation between the gate stack 104 and source/drain contacts of the transistor and could be made of a low-k dielectric material. Some examples of low-k dielectric materials include, but are not limited to, silicon dioxide, carbon-doped oxide, silicon nitride, organic polymers such as perfluorocyclobutane or polytetrafluoroethylene, fused silica glass (FSG), and organosilicates such as silsesquioxane, siloxane, or organosilicate glass. A gate spacer may include pores or air gaps to further reduce its dielectric constant.

In some embodiments, e.g., when a transistor (e.g., any of the transistors 120 discussed herein) is a storage transistor of a hysteretic memory cell (i.e., a type of memory that functions based on the phenomenon of hysteresis), the gate insulator material 106 may be replaced with, or complemented by, a hysteretic material or a hysteretic arrangement, which, together, may be referred to as a “hysteretic element.” Transistors in which the gate insulator material 106 includes a hysteretic element may be described as “hysteretic transistors” and may be used to implement hysteretic memory. Hysteretic memory refers to a memory technology employing hysteretic materials or arrangements, where a material or an arrangement may be described as hysteretic if it exhibits the dependence of its state on the history of the material (e.g., on a previous state of the material). Ferroelectric (FE) and antiferroelectric (AFE) materials are one example of hysteretic materials. Layers of different materials arranged in a stack to exhibit charge-trapping phenomena is one example of a hysteretic arrangement.

A FE or an AFE material is a material that exhibits, over some range of temperatures, spontaneous electric polarization, i.e., displacement of positive and negative charges from their original position, where the polarization can be reversed or reoriented by application of an electric field. In particular, an AFE material is a material that can assume a state in which electric dipoles from the ions and electrons in the material may form a substantially ordered (e.g., substantially crystalline) array, with adjacent dipoles being oriented in opposite (antiparallel) directions (i.e., the dipoles of each orientation may form interpenetrating sub-lattices, loosely analogous to a checkerboard pattern), while a FE material is a material that can assume a state in which all of the dipoles point in the same direction. Because the displacement of the charges in FE and AFE materials can be maintained for some time even in the absence of an electric field, such materials may be used to implement memory cells. Because the current state of the electric dipoles in FE and AFE materials depends on the previous state, such materials are hysteretic materials. Memory technology where logic states are stored in terms of the orientation of electric dipoles in (i.e., in terms of polarization of) FE or AFE materials is referred to as “FE memory,” where the term “ferroelectric” is said to be adopted to convey the similarity of FE memories to ferromagnetic memories, despite the fact that there is typically no iron (Fe) present in FE or AFE materials.

A stack of alternating layers of materials that is configured to exhibit charge-trapping is an example of a hysteretic arrangement. Such a stack may include as little as two layers of materials, one of which is a charge-trapping layer (i.e., a layer of a material configured to trap charges when a volage is applied across the material) and the other one of which is a tunnelling layer (i.e., a layer of a material through which the charge is to be tunneled to the charge-trapping layer). The tunnelling layer may include an insulator material such as a material that includes silicon and oxygen (e.g., silicon oxide), or any other suitable insulator. The charge-trapping layer may include a metal or a semiconductor material that is configured to trap charges. For example, a material that includes silicon and nitrogen (e.g., silicon nitride) may be used in/as a charge-trapping layer. Because the trapped charges may be kept in a charge-trapping arrangement for some time even in the absence of an electric field, such arrangements may be used to implement memory cells. Because the presence and/or the amount of trapped charges in a charge-trapping arrangement depends on the previous state, such arrangements are hysteretic arrangements. Memory technology where logic states are stored in terms of the amount of charge trapped in a hysteretic arrangement may be referred to as “charge-trapping memory.”

Hysteretic memories have the potential for adequate non-volatility, short programming time, low power consumption, high endurance, and high speed writing. In addition, hysteretic memories may be manufactured using processes compatible with the standard CMOS technology. Therefore, over the last few years, these types of memories have emerged as promising candidates for many growing applications.

In some embodiments, the hysteretic element of the gate insulator material 106 may be provided as a layer of a FE or an AFE material. Such an FE/AFE material may include one or more materials that can exhibit sufficient FE/AFE behavior even at thin dimensions, e.g., such as an insulator material at least about 5%, e.g., at least about 7% or at least about 10%, of which is in an orthorhombic phase and/or a tetragonal phase (e.g., as a material in which at most about 95-90% of the material may be amorphous or in a monoclinic phase). For example, such materials may be based on hafnium and oxygen (e.g., hafnium oxides), with various dopants added to ensure sufficient amount of an orthorhombic phase or a tetragonal phase. Some examples of such materials include materials that include hafnium, oxygen, and zirconium (e.g., hafnium zirconium oxide (HfZrO, also referred to as HZO)), materials that include hafnium, oxygen, and silicon (e.g., silicon-doped (Si-doped) hafnium oxide), materials that include hafnium, oxygen, and germanium (e.g., germanium- doped (Ge-doped) hafnium oxide), materials that include hafnium, oxygen, and aluminum (e.g., aluminum-doped (Al-doped) hafnium oxide), and materials that include hafnium, oxygen, and yttrium (e.g., yttrium-doped (Y-doped) hafnium oxide). However, in other embodiments, any other materials which exhibit FE/AFE behavior at thin dimensions may be used as the hysteretic element and are within the scope of the present disclosure.

In other embodiments, the hysteretic element of the gate insulator material 106 may be provided as a stack of alternating layers of materials that can trap charges. In some such embodiments, the stack may be a two-layer stack, where one layer is a charge-trapping layer, and the other layer is a tunnelling layer. The tunnelling layer may include an insulator material such as a material that includes silicon and oxygen (e.g., silicon oxide), or any other suitable insulator. The charge-trapping layer may include an electrically conductive material such as a metal, or a semiconductor material. In some embodiments, the charge-trapping layer may include a material that includes silicon and nitrogen (e.g., silicon nitride). In general, any material that has defects that can trap charge may be used in/as a charge-trapping layer. Such defects are very detrimental to operation of logic devices and, therefore, typically, deliberate steps need to be taken to avoid presence of the defects. However, for memory devices, such defects are desirable because charge-trapping may be used to represent different memory states of a memory cell.

In some embodiments of the hysteretic element being provided as a stack of alternating layers of materials that can trap charges, the stack may be a three-layer stack where an insulator material is provided on both sides of a charge-trapping layer. In such embodiments, a layer of an insulator material on one side of the charge-trapping layer may be referred to as a “tunnelling layer” while a layer of an insulator material on the other side of the charge-trapping layer may be referred to as a “field layer.”

In various embodiments of the hysteretic element being provided as a stack of alternating layers of materials that can trap charges, a thickness of each layer the stack may be between about 0.5 and 10 nanometers, including all values and ranges therein, e.g., between about 0.5 and 5 nanometers. In some embodiment of a three-layer stack, a thickness of each layer of the insulator material may be about 0.5 nanometers, while a thickness of the charge-trapping layer may be between about 1 and 8 nanometers, e.g., between about 2.5 and 7.5 nanometers, e.g., about 5 nanometers. In some embodiments, a total thickness of the hysteretic element provided as a stack of alternating layers of materials that can trap charges (i.e., a hysteretic arrangement) may be between about 1 and 10 nanometers, e.g., between about 2 and 8 nanometers, e.g., about 6 nanometers.

The dimensions of the elements of an IC structure 100 may take any suitable values. For example, the channel structure 102 may have a thickness 113. In some embodiments, the thickness 113 may be between about 5 nanometers and 100 nanometers, e.g., between about 5 nanometers and 30 nanometers, or between about 5 nanometers and 10 nanometers. The gate insulator material 106 may have a thickness 114. In some embodiments, the thickness 114 may be between about 0.5 nanometers and 3 nanometers, e.g., between about 1 nanometer and 3 nanometers, or between about 1 nanometer and 2 nanometers. In other embodiments, the thickness 114 may be as described above with reference to hysteretic elements.

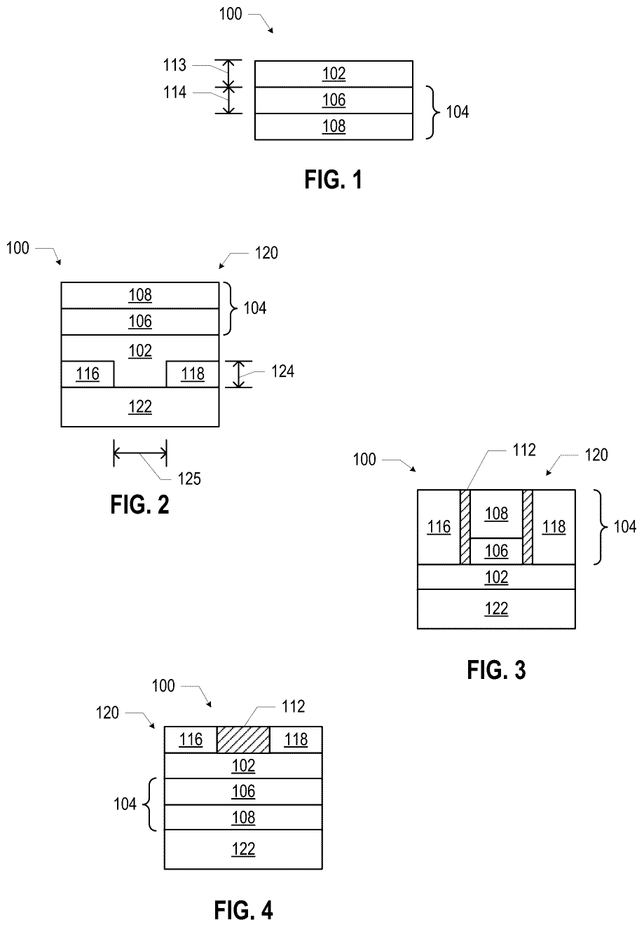

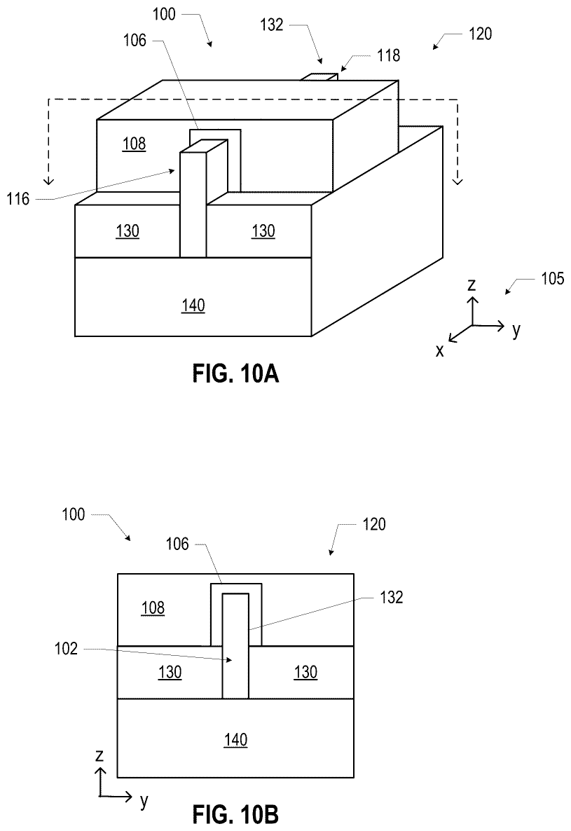

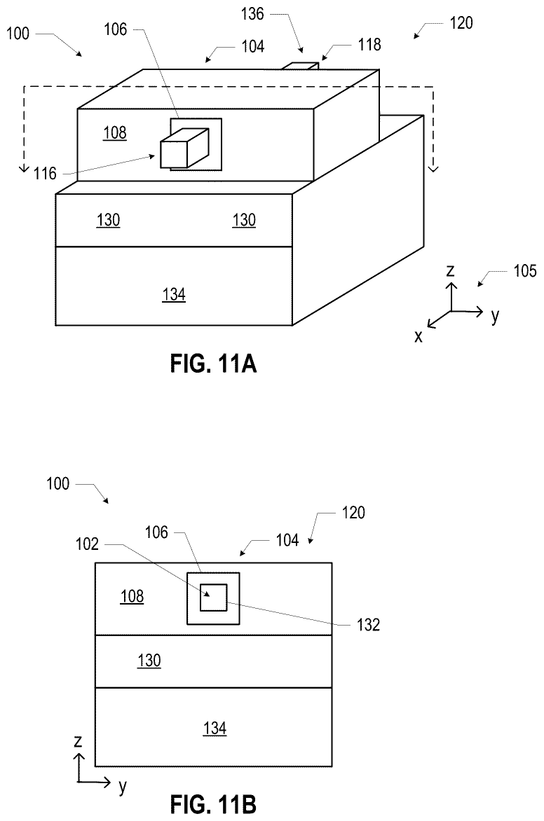

The channel structure 102 may be included in any suitable transistor structure. For example, FIGS. 2-6 are cross-sectional side views of example single-gate transistors 120 including a channel structure 102, FIGS. 7-9 are cross-sectional side views of example double-gate transistors 120 including a channel structure 102, FIGS. 10A and 10B are perspective and cross-sectional side views, respectively, of an example tri-gate transistor 120 including a channel structure 102, and FIGS. 11A and 11B are perspective and cross-sectional side views, respectively, of an example all-around gate transistor 120 including a channel structure 102, in accordance with various embodiments. The transistors 120 illustrated in FIGS. 2-11 do not represent an exhaustive set of transistor structures in which a channel structure 102 may be included, but provide examples of such structures. Note that FIGS. 2-6 are intended to show relative arrangements of the components therein, and the transistors 120 may include other components that are not illustrated (e.g., electrical contacts to the gate electrode materials 108, etc.). Any of the components of the transistors 120 discussed below with reference to FIGS. 2-11 may take the form of any of the embodiments of those components discussed above with reference to FIG. 1. Additionally, although various components of the transistors 120 are illustrated in FIGS. 2-11 as being planar rectangles or formed of rectangular solids, this is simply for ease of illustration, and embodiments of these transistors 120 may be curved, rounded, or otherwise irregularly shaped as dictated by the manufacturing processes used to fabricate the transistors 120. The transistors 120 of FIGS. 2-3 may be referred to as “top gate” transistors, while the transistors 120 of FIGS. 4-6 may be referred to as “bottom gate” transistors. Similarly, the transistors 120 of FIGS. 2 and 6 may be referred to as “bottom contact” transistors, while the transistors 120 of FIGS. 3-5 may be referred to as “top contact” transistors.

FIG. 2 depicts a transistor 120 including a channel structure 102 and having a single “top” gate provided by the gate electrode material 108 and the gate insulator material 106. The gate insulator material 106 may be disposed between the gate electrode material 108 and the channel structure 102. In the embodiment of FIG. 2, the gate stack 104 is shown as disposed above a support 122. The support 122 may be any structure on which the gate stack 104, or other elements of the transistor 120, is disposed. In some embodiments, the support 122 may include a semiconductor, such as silicon. In some embodiments, the support 122 may include an insulating layer, such as an oxide isolation layer. For example, in the embodiments of FIGS. 2 and 3, the support 122 may include a semiconductor material and an interlayer dielectric (ILD) disposed between the semiconductor material and the source/drain (S/D) contact 116, the channel structure 102, and the S/D contact 118, to electrically isolate the semiconductor material of the support 122 from the S/D contact 116, the channel structure 102, and the S/D contact 118 (and thereby mitigate the likelihood that a conductive pathway will form between the S/D contact 116 and the S/D contact 118 through the support 122). Examples of ILDs that may be included in a support 122 in some embodiments may include silicon oxide, silicon nitride, aluminum oxide, and/or silicon oxynitride. Any suitable ones of the embodiments of the support 122 described with reference to FIG. 2 may be used for the supports 122 of others of the transistors 120 disclosed herein.

As noted above, the transistor 120 may include an S/D contact 116 and an S/D contact 118 disposed on the support 122, with the channel structure 102 disposed between the S/D contact 116 and the S/D contact 118 so that at least some of the channel structure 102 is coplanar with at least some of the S/D contact 116 and the S/D contact 118. The S/D contact 116 and the S/D contact 118 may have a thickness 124. In some embodiments, the thickness 124 may be less than the thickness 113 (as illustrated in FIG. 2, with the S/D contact 116 and the S/D contact 118 each disposed between some of the channel structure 102 and the support 122), while in other embodiments, the thickness 124 may be equal to the thickness 113. In some embodiments, the channel structure 102, the gate insulator material 106, and/or the gate electrode material 108 may conform around the S/D contact 116 and/or the S/D contact 118. The S/D contact 116 and the S/D contact 118 may be spaced apart by a distance 125 that is the gate length of the transistor 120. In some embodiments, the gate length may be between 20 nanometers and 30 nanometers (e.g., between 22 nanometers and 28 nanometers, or approximately 25 nanometers).

The S/D contact 116 and the S/D contact 118 may be formed using any suitable processes known in the art. For example, one or more layers of metal and/or metal alloys may be deposited or otherwise provided to form the S/D contact 116 and the S/D contact 118, as known for thin-film transistors based on semiconductor oxide systems. Any suitable ones of the embodiments of the S/D contact 116 and the S/D contact 118 described above may be used for any of the S/D contacts 116 and S/D contacts 118 described herein.

FIG. 3 depicts a transistor 120 including a channel structure 102 and having a single “top” gate provided by the gate electrode material 108 and the gate insulator material 106. The gate insulator material 106 may be disposed between the gate electrode material 108 and the channel structure 102. In the embodiment of FIG. 3, the gate stack 104 is shown as disposed above a support 122. The transistor 120 may include an S/D contact 116 and an S/D contact 118 disposed on the support 122. As discussed above, in some embodiments, the support 122 of FIG. 3 may include a semiconductor material and ILD disposed between the semiconductor material and the S/D contact 116, the channel structure 102, and the S/D contact 118, to electrically isolate the semiconductor material of the support 122 from the S/D contact 116, the channel structure 102, and the S/D contact 118. In some embodiments, the gate insulator material 106 and/or the gate electrode material 108 may conform around the S/D contact 116 and/or the S/D contact 118. An insulating material 112 may be disposed between the S/D contacts 116/118 and the gate stack 104; the insulating material 112 may include any suitable insulating material, such as any of the ILDs discussed herein. Insulating material 112 on a channel structure 102 may include a passivation material (e.g., hafnium oxide, zirconium oxide, aluminum oxide, silicon oxide, silicon nitride, silicon carbide, silicon oxycarbide, silicon oxynitride, titanium oxide, copper oxide, tin oxide, or copper tin oxide) in contact with the channel structure 102. In some embodiments, the channel structure 102 may include a semiconductor material with an insulating material dopant and/or an opposite conductivity type dopant proximate to the passivation material, and another material (e.g., a non-doped semiconductor material) distal to the passivation material (e.g., so that the semiconductor material with an insulating material dopant and/or an opposite conductivity type dopant is between the non-doped semiconductor material and the insulating material 112).

FIG. 4 depicts a transistor 120 including a transistor gate stack 104 and having a single “bottom” gate provided by the gate electrode material 108 and the gate insulator material 106. The gate insulator material 106 may be disposed between the gate electrode material 108 and the channel structure 102. In the embodiment of FIG. 4, the gate stack 104 is shown as disposed on a support 122 in an orientation “upside down” to the one illustrated in FIG. 2; that is, the gate electrode material 108 may be disposed between the support 122 and the channel structure 102. The transistor 120 may include an S/D contact 116 and an S/D contact 118 disposed on the channel structure 102 such that the S/D contact 116 and the S/D contact 118 are not coplanar with the channel structure 102. An insulating material 112 may be disposed between the S/D contacts 116 and 118, above the channel structure 102.

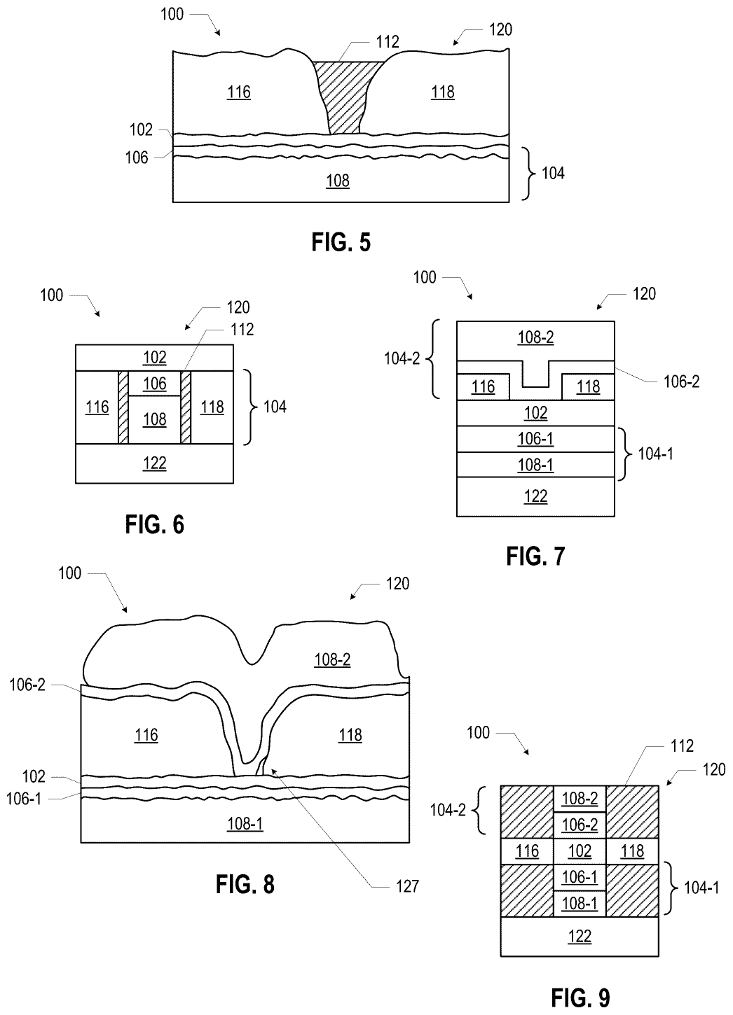

FIG. 5 depicts a transistor 120 having the structure of the transistor 120 of FIG. 4. In particular, the transistor 120 of FIG. 5 includes a transistor gate stack 104 and has a single “bottom” gate provided by the gate electrode material 108 and the gate insulator material 106. The transistor 120 of FIG. 5 may also include a support 122 (not shown) arranged so that the gate electrode material 108 is disposed between the support 122 and the gate insulator material 106. The transistor 120 may include an S/D contact 116 and an S/D contact 118 disposed on the channel structure 102 such that the S/D contact 116 and the S/D contact 118 are not coplanar with the channel structure 102. Any suitable materials may be used to form the transistor 120 of FIG. 5, as discussed above. For example, the gate electrode material 108 may include titanium nitride, the gate insulator material 106 may include hafnium oxide, and the S/D contact 116 and the S/D contact 118 may include aluminum. The gate length of the transistor 120 of FIG. 5 may be approximately 25 nanometers.

FIG. 6 depicts a transistor 120 including a transistor gate stack 104 and having a single “bottom” gate provided by the gate electrode material 108 and the gate insulator material 106. The gate insulator material 106 may be disposed between the gate electrode material 108 and the channel structure 102. In the embodiment of FIG. 6, the gate stack 104 is shown as disposed on a support 122 in an orientation “upside down” to the one illustrated in FIG. 2; that is, the gate electrode material 108 may be disposed between the support 122 and the channel structure 102. The transistor 120 may include an S/D contact 116 and an S/D contact 118 disposed on the channel structure 102 such that at least some of the S/D contact 116 and at least some of the S/D contact 118 are coplanar with at least some of the channel structure 102. In some embodiments, the S/D contact 116 and the S/D contact 118 may each be disposed between some of the channel structure 102 and the support 122, as illustrated in FIG. 6, while in other embodiments, the channel structure 102 may not extend “above” the S/D contact 116 or the S/D contact 118. In some embodiments, the channel structure 102 may conform around the S/D contact 116 and/or the S/D contact 118.

FIG. 7 depicts a double-gate transistor 120 including two transistor gate stacks 104-1 and 104-2 and having “bottom” and “top” gates provided by the gate electrode material 108-1/gate insulator material 106-1 and the gate electrode material 108-2/gate insulator material 106-2, respectively. Each gate insulator material 106 may be disposed between the corresponding gate electrode material 108 and the channel structure 102. The transistor 120 may include an S/D contact 116 and an S/D contact 118 disposed proximate to the channel structure 102. In the embodiment illustrated in FIG. 7, the S/D contact 116 and the S/D contact 118 are disposed on the channel structure 102, and the gate insulator material 106-2 is disposed conformably around the S/D contact 116, the channel structure 102, and the S/D contact 118. The gate electrode material 108-2 is disposed on the gate insulator material 106-2. In the embodiment of FIG. 7, at least some of the S/D contact 116 and at least some of the S/D contact 118 are coplanar with at least some of the gate insulator material 106-2.

FIG. 8 depicts a double-gate transistor 120 having the structure of the transistor 120 of FIG. 7. In particular, the transistor 120 of FIG. 8 includes two transistor gate stacks 104-1 and 104-2 and having “bottom” and “top” gates provided by the gate electrode material 108-1/gate insulator material 106-1 and the gate electrode material 108-2/gate insulator material 106-2, respectively. The transistor 120 of FIG. 8 may also include a support 122 (not shown) arranged so that the gate electrode material 108-1 is disposed between the support 122 and the gate insulator material 106. The transistor 120 may include an S/D contact 116 and an S/D contact 118 disposed on the channel structure 102 such that the S/D contact 116 and the S/D contact 118 are not coplanar with the channel structure 102. In the embodiment depicted in FIG. 8, the S/D contact 116 and the S/D contact 118 may be deposited on the channel structure 102. During manufacture, a void 127 may be formed between the gate insulator material 106-2 and the channel structure 102; while such voids 127 may reduce the performance of the transistor 120, the transistor 120 may still function adequately as long as adequate coupling between the gate insulator material 106-2 and the channel structure 102 is achieved. Any suitable materials may be used to form the transistor 120 of FIG. 8, as discussed above. For example, the gate electrode material 108-1 may be titanium nitride, the gate insulator materials 106-1 and 106-2 may include hafnium oxide, the S/D contact 116 and the S/D contact 118 may include aluminum, and the gate electrode material 108-2 may include palladium. In some embodiments, the gate length of the transistor 120 of FIG. 8 may be approximately 25 nanometers.

FIG. 9 depicts a double-gate transistor 120 including two transistor gate stacks 104-1 and 104-2 and having “bottom” and “top” gates provided by the gate electrode material 108-1/gate insulator material 106-1 and the gate electrode material 108-2/gate insulator material 106-2, respectively. Each gate insulator material 106 may be disposed between the corresponding gate electrode material 108 and the channel structure 102. The transistor 120 may include an S/D contact 116 and an S/D contact 118 disposed proximate to the channel structure 102. In the embodiment illustrated in FIG. 9, the S/D contact 116 and the S/D contact 118 are coplanar with the channel structure 102, and disposed between the gate insulator materials 106-1 and 106-2. The relative arrangement of the S/D contact 116, the S/D contact 118, and the channel structure 102 may take the form of any of the embodiments discussed above with reference to FIG. 2.

FIGS. 10A and 10B are perspective and cross-sectional side views, respectively, of an example tri-gate transistor 120 including a fin 132 that may include a channel structure 102, in accordance with various embodiments. In the tri-gate transistor 120 illustrated in FIGS. 10A and 10B, a fin 132 formed of a semiconductor material may extend from a base 140 of the semiconductor material. The base 140 may be any structure from which the fin 132 may extend; descriptions provided for the support 122 are applicable to the base 140. An oxide material 130 may be disposed on either side of the fin 132. In some embodiments, the oxide material 130 may include a shallow trench isolation (STI) material. The transistor 120 of FIGS. 10A and 10B may include a channel structure 102 in the fin 132, and may further include a gate stack 104 including a gate electrode material 108 and a gate insulator material 106. FIG. 10A is a perspective drawing, an example coordinate system 105 (x-y-z coordinate system) is shown there to assist explanations. The coordinate system 105 is also shown in FIG. 11A, and other drawings illustrating axes (e.g., FIG. 10B, FIG. 11B, and FIGS. 12A-12C illustrating y-z planes, or FIGS. 13A-13F illustrating x-z planes) refer to the coordinate system 105.

The gate stack 104 may wrap around the fin 132 as shown, with the channel structure 102 corresponding to the portion of the fin 132 wrapped by the gate stack 104. The fin 132 may include an S/D contact 116 and an S/D contact 118 on either side of the gate stack 104, as shown. The composition of the channel structure 102, the S/D contact 116, and the S/D contact 118 may take the form of any of the embodiments disclosed herein, or known in the art. Although the fin 132 illustrated in FIGS. 10A and 10B is shown as having a rectangular cross section, the fin 132 may instead have a cross section that is rounded or sloped at the “top” of the fin 132, and the gate stack 104 may conform to this rounded or sloped fin 132. In use, the tri-gate transistor 120 may form conducting channels on three “sides” of the fin 132, potentially improving performance relative to single-gate transistors (which may form conducting channels on one “side” of the channel structure 102) and double-gate transistors (which may form conducting channels on two “sides” of the channel structure 102).

FIGS. 11A and 11B are perspective and cross-sectional side views, respectively, of an example all-around gate transistor 120 including a wire 136 that may include a channel structure 102, in accordance with various embodiments. In the all-around gate transistor 120 illustrated in FIGS. 11A and 11B, a wire 136 formed of a semiconductor material may extend above a support 134 and a layer of oxide material 130. The support 134 may be any structure from over which the wire 136 may extend; descriptions provided for the support 122 are applicable to the support 134. The wire 136 may take the form of a nanowire or nanoribbon, for example. The transistor 120 of FIGS. 11A and 11B may further include a channel structure 102 in the wire 136, and a gate stack 104 including a gate electrode material 108 and a gate insulator material 106. The gate stack 104 may wrap entirely or almost entirely around the wire 136, as shown, with the channel structure 102 corresponding to the portion of the wire 136 wrapped by the gate stack 104. In some embodiments, the gate stack 104 may fully encircle the wire 136. The wire 136 may include an S/D contact 116 and an S/D contact 118 on either side of the gate stack 104, as shown. The composition of the channel structure 102, the S/D contact 116, and the S/D contact 118 may take the form of any of the embodiments disclosed herein, or known in the art. Although the wire 136 illustrated in FIGS. 11A and 11B is shown as having a rectangular cross section, the wire 136 may instead have a cross section that is rounded or otherwise irregularly shaped, and the gate stack 104 may conform to the shape of the wire 136. In use, the tri-gate transistor 120 may form conducting channels on more than three “sides” of the wire 136, potentially improving performance relative to tri-gate transistors. Although FIGS. 11A and 11B depict an embodiment in which the longitudinal axis of the wire 136 runs substantially parallel to a plane of the oxide material 130 (and a plane of the support 134), this need not be the case; in other embodiments, for example, the wire 136 may be oriented “vertically” so as to be perpendicular to a plane of the oxide material 130 (or plane of the support 134).

FIGS. 12A-12C are cross-sectional side views of different examples of the channel structures 102 combining portions of GaN and SiC stacked above one another, in accordance with various embodiments. FIGS. 12A-12C illustrate cross-sectional side views of y-z planes of the coordinate system 105, e.g., views of a transverse cross-section of the fin 132 or the wire 136 (i.e., a cross-section in a plane perpendicular to the longitudinal axis of the fin 132 or the wire 136), in case the channel structure 102 is implemented within, respectively, the fin 132 or the wire 136. More generally, FIGS. 12A-12C illustrate cross-sectional side views of the channel structure 102 in a plane that is perpendicular to the direction of the gate length of a transistor (e.g., any of the transistors 120 discussed herein).

As shown in FIGS. 12A-12C, a channel structure 102 may include a first portion 201, a second portion 202, and a third portion 203 that are separate and distinct from one another and are stacked above one another (i.e., vertically stacked) so that the second portion 202 is stacked above (and may be in contact with) the first portion 201, and the third portion 203 is stacked above (and may be in contact with) the second portion 202. Thus, the second portion 202 is between the first portion 201 and the third portion 203 along the height of the channel structure 102. FIGS. 12A-12C use the same pattern to show the first portion 201 and the third portion 203 to indicate that these two portions may include substantially the same semiconductor material, while the second portion 202 includes a different semiconductor material. For example, in some embodiments, the first portion 201 and the third portion 203 may include GaN, while the second portion 202 may include SiC. In other embodiments, the first portion 201 and the third portion 203 may include SiC, while the second portion 202 may include GaN.

The channel structure 102 as shown in FIGS. 12A-12C may be part of a channel region of a transistor. Alternatively, the channel structure 102 as shown in FIGS. 12A-12C may be part of a source region or a drain region of a transistor (i.e., may be a part of a S/D region of a transistor, e.g., a part of one of the S/D regions 2120 described below with reference to FIG. 15) and the S/D contact 116 and the S/D contact 118 may be in contact with or may be a part of the channel structure 102 on either side of a channel region. In some embodiments, the S/D regions may be highly doped, e.g., with dopant concentrations of at least about 1×10¹⁸ dopants per cubic centimeter (cm³), e.g., of at least about 1×10²⁰ cm⁻³, or of at least about 1×10²¹ cm³, in order to advantageously form Ohmic contacts with the respective S/D contacts (not shown in FIGS. 12A-12C, e.g., with the S/D contact 116 and the S/D contact 118), although these regions may also have lower dopant concentrations and may form Schottky contacts in some implementations. Irrespective of the exact doping levels, the S/D regions of a transistor are the regions having dopant concentration higher than in other regions, e.g., higher than a dopant concentration in the channel region (i.e., in a channel material extending between the first S/D region and the second S/D region), and, therefore, may be referred to as “highly doped” regions.

As shown in FIGS. 12A-12C, the first portion 201 may have a thickness 211, the second portion 202 may have a thickness 212, and the third portion 203 may have a thickness 213. FIG. 12A illustrates an embodiment where the thickness 211 is substantially the same as the thickness 213. FIG. 12B illustrates an embodiment where the thickness 211 is smaller than the thickness 213. FIG. 12C illustrates an embodiment where the thickness 211 is larger than the thickness 213. In some embodiments, a minimum thickness for each of the thickness 211, the thickness 212, and the thickness 213 may be about 1 nanometer. In some embodiments, a sum of the thickness 211, the thickness 212, and the thickness 213 may be between about 5 nanometers and 100 nanometers. In some embodiments, the thickness 212 may be 1.5 times or more larger than the thickness 211 or the thickness 213. In other words, in some embodiments, a ratio of the thickness 212 to either the thickness 211 or the thickness 213 may be 1.5 or larger, or the thickness 212 is at least about 50% larger than the thickness 211 or the thickness 213. Thicknesses of different portions 202, 202, and 203 of the channel structures 102 FIGS. 12A-12C selected according to principles described herein may help optimize performance of a transistor (e.g., any of the transistors 120 discussed herein) in terms of one or more competing parameters, such as breakdown voltage of a transistor (e.g., may help optimize performance of a transistor while maintaining adequate breakdown voltage).

FIGS. 13A-13F are cross-sectional side views of different examples of the channel structures combining portions of GaN and SiC arranged sequentially along the gate length of a transistor, in accordance with various embodiments. FIGS. 13A-13F illustrate cross-sectional side views of x-z planes of the coordinate system 105, e.g., views of a longitudinal cross-section of the fin 132 or the wire 136 (i.e., a cross-section in a plane that includes the longitudinal axis of the fin 132 or the wire 136), in case the channel structure 102 is implemented within, respectively, the fin 132 or the wire 136. More generally, 13A-13F illustrate cross-sectional side views of the channel structure 102 in a plane that extends along the direction of the gate length of a transistor (e.g., any of the transistors 120 discussed herein).

The channel structures 102 shown in FIGS. 13A-13F are similar to those shown in FIGS. 12A-12C in that they also include the first portion 201, the second portion 202, and the third portion 203 which may include materials as described as described above. However, while FIGS. 12A-12C illustrate stacking of the portions in the vertical direction (i.e., the first portion 201, the second portion 202, and the third portion 203 are stacked along the height of the channel structure 102), in FIGS. 13A-13F the portions are stacked laterally (i.e., side by side) along the gate length of a transistor (e.g., any of the transistors 120 discussed herein). Thus, while in FIGS. 12A-12C, the portions 201, 202, and 203 are in different layers above a support (e.g., above a substrate), in FIGS. 13A-13F the portions 201, 202, and 203 are in a single layer, arranged side by side along the gate length. Hence, FIGS. 13A-13F illustrate cross-sectional side views of x-z planes of the coordinate system 105.

Although not specifically shown in FIGS. 13A-13F in order to not clutter the drawing, in some embodiments, the S/D contact 116 may be contact with or may be a part of the first portion 201, while the S/D contact 118 may be contact with or may be a part of the third portion 203. In some such embodiments, at least a portion of the first portion 201 and at least a portion of the third portion 203 may serve as, respectively, a first S/D region (e.g., a source region) and a second S/D region (e.g., a drain region) of a transistor, e.g., any of the S/D regions 2120 described below with reference to FIG. 15.

As shown in FIGS. 13A-13F, the first portion 201 may have a length 221, the second portion 202 may have a length 222, and the third portion 203 may have a length 223, where the lengths 221, 222, and 223 may be dimensions of the respective portions 201, 202, and 203 along a direction of a gate length of the transistor. FIG. 13A illustrates an embodiment where the length 221 is substantially the same as the length 223. FIG. 13B illustrates an embodiment where the length 221 is smaller than the length 223. FIG. 13C illustrates an embodiment where the length 221 is larger than the length 223. In some embodiments, the length 222 may be between about 20 nanometers and 500 nanometers. In some embodiments, the length 221 or the length 223 may be between about 10% and 80% of the length 222. Lengths of different portions 201, 202, 203 of the channel structures 102 of FIGS. 13A-13F selected according to principles described herein may help optimize performance of a transistor (e.g., any of the transistors 120 discussed herein) in terms of one or more competing parameters, such as breakdown voltage of a transistor (e.g., may help optimize performance of a transistor while maintaining adequate breakdown voltage).

FIGS. 13A-13C illustrate embodiments where thicknesses of all of the portions 201, 202, and 203 (i.e., dimensions measured along the z-axis of the coordinate system 105) are substantially the same. For example, the thickness of all of the portions 201, 202, and 203 of the channel structures 102 of FIGS. 13A-13C may be at least about 10 nanometers.

In other embodiments, thicknesses of different portions 201, 202, and 203 may be different from one another, as is shown in FIGS. 13A-13C. In some such embodiments, a minimum thickness for each of the portions 201, 202, and 203 of the channel structures 102 of FIGS. 13A-13F may be about 10 nanometers. FIG. 13D illustrates an embodiment where the thickness 212 is substantially the same as the thickness 213 and the thickness 211 is smaller than the thickness 212. Although not specifically shown, in some embodiments, the thickness 212 may be substantially the same as the thickness 213, but the thickness 211 may be larger than the thickness 212. FIG. 13E illustrates an embodiment where the thickness 211 is substantially the same as the thickness 213 and the thickness 211 is smaller than the thickness 212. Although not specifically shown, in some embodiments, the thickness 211 may be substantially the same as the thickness 213, but the thickness 211 may be larger than the thickness 212. FIG. 13F illustrates an embodiment where the thickness 213 is larger than the thickness 211, and the thickness 212 is larger than the thickness 213. Although not specifically shown, in some embodiments, relations between the thickness 211, the thickness 212, and the thickness 213 of the channel structures 102 of FIGS. 13A-13F may be different and, in general, all of the thicknesses 211, 212, and 213 may be different. Thicknesses of different portions 201, 202, 203 of the channel structures 102 of FIGS. 13A-13F selected according to principles described herein may help optimize performance of a transistor (e.g., any of the transistors 120 discussed herein) in terms of one or more competing parameters, such as breakdown voltage of a transistor (e.g., may help optimize performance of a transistor while maintaining adequate breakdown voltage).

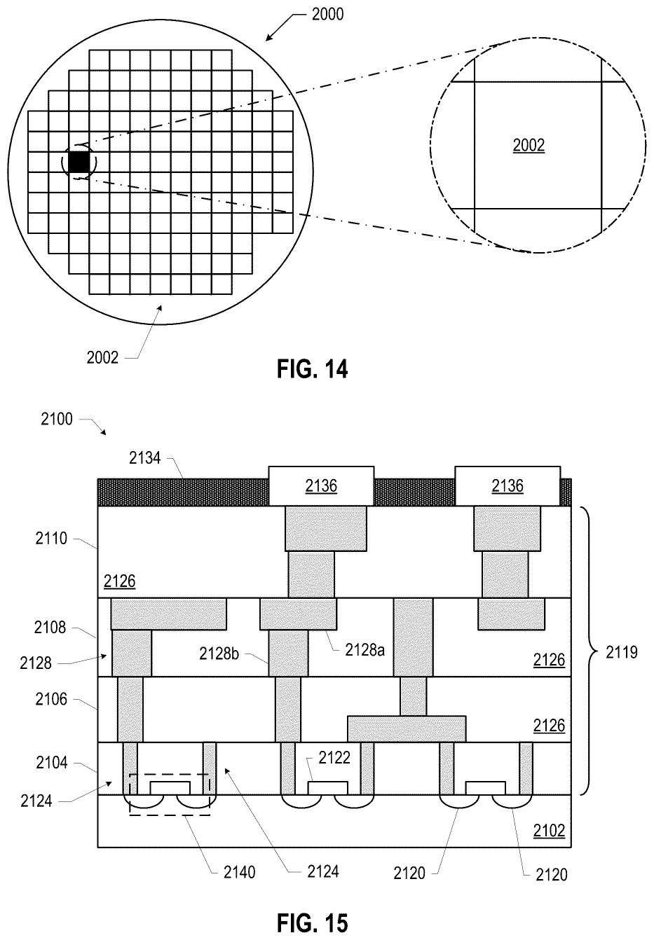

The IC structures with transistor channel structures combining GaN and SiC disclosed herein (e.g., any of the IC structures described with reference to FIGS. 1-13) may be included in any suitable electronic device. FIGS. 14-19 illustrate various examples of apparatuses that may include one or more IC structures with transistor channel structures combining GaN and SiC disclosed herein, e.g., with any embodiment of the channel structures 102 as shown in FIGS. 12A-12C or FIGS. 13A-13F, or any combination of such embodiments.

FIG. 14 illustrates top views of a wafer and dies that include one or more IC structures with transistor channel structures combining GaN and SiC (e.g., with any of the channel structures 102 described herein) in accordance with any of the embodiments disclosed herein. The wafer 2000 may be composed of semiconductor material and may include one or more dies 2002 having IC structures formed on a surface of the wafer 2000. Each of the dies 2002 may be a repeating unit of a semiconductor product that includes any suitable IC structure (e.g., any of the IC structures described with reference to FIGS. 1-13). After the fabrication of the semiconductor product is complete (e.g., after manufacture of one or more IC structures with one or more channel structures 102 as described herein), the wafer 2000 may undergo a singulation process in which each of the dies 2002 is separated from one another to provide discrete “chips” of the semiconductor product. In particular, devices that include one or more IC structures with one or more channel structures 102 as disclosed herein may take the form of the wafer 2000 (e.g., not singulated) or the form of the die 2002 (e.g., singulated). The die 2002 may include one or more channel structures 102 included within any transistor, one or more transistors (e.g., any of the transistors 120 of FIGS. 2-11, discussed above, or any of the transistors 2140 of FIG. 15, discussed below), and/or supporting circuitry to route electrical signals to the channel structures 102, as well as any other IC components. In some embodiments, the wafer 2000 or the die 2002 may include a memory device (e.g., a memory device with one or more channel structures 102), a logic device (e.g., an AND, OR, NAND, or NOR gate, or any other logic device with one or more channel structures 102), or any other suitable circuit element. Multiple ones of these devices may be combined on a single die 2002. For example, a memory array formed by multiple memory devices may be formed on a same die 2002 as a processing device (e.g., the processing device 2500 of FIG. 19) or other logic that is configured to store information in the memory devices or execute instructions stored in the memory array.

FIG. 15 is a side, cross-sectional view of an IC device 2100 that may include one or more IC structures with transistor channel structures combining GaN and SiC (e.g., with any of the channel structures 102 described herein), in accordance with various embodiments. For example, any of the channel structures 102 described herein may be included in one or more of the transistors 2140 of the IC device 2100. In another example, one or more of the IC devices 2100 may be included in one or more dies 2002 of FIG. 14. The IC device 2100 may be formed on a substrate 2102 (e.g., the wafer 2000 of FIG. 14) and may be included in a die (e.g., the die 2002 of FIG. 14). The substrate 2102 may take on any forms of the support 122, the base 140, or the support 134, described above.

The IC device 2100 may include one or more device layers 2104 disposed on the substrate 2102. The device layer 2104 may include features of one or more transistors 2140 (e.g., metal oxide semiconductor field-effect transistors (MOSFETs)) formed on the substrate 2102. The device layer 2104 may include, for example, one or more S/D regions 2120, a gate 2122 to control current flow in the transistors 2140 between the S/D regions 2120, and one or more S/D contacts 2124 (e.g., any of the S/D contacts 116 or 118, described above) to route electrical signals to/from the S/D regions 2120. The transistors 2140 may include additional features not depicted for the sake of clarity, such as device isolation regions, gate contacts, and the like. The transistors 2140 are not limited to the type and configuration depicted in FIG. 15 and may include a wide variety of other types and configurations such as, for example, planar transistors, non-planar transistors, or a combination of both. Planar transistors may include bipolar junction transistors (BJT), heterojunction bipolar transistors (HBT), or high-electron-mobility transistors (HEMT). Non-planar transistors may include FinFET transistors, such as double-gate transistors or tri-gate transistors, and wrap-around or all-around gate transistors, such as nanoribbon and nanowire transistors. In some embodiments, any of the transistors 2140 may be implemented as any of the transistors 120, described above.

Each transistor 2140 may include a gate 2122 formed of at least two layers, a gate insulator and a gate electrode. Descriptions provided above for the gate stack 104 are applicable to the gate 2122.

The S/D regions 2120 may be formed within the substrate 2102 adjacent to the gate 2122 of each transistor 2140. The S/D regions 2120 may be formed using an implantation/diffusion process or an etching/deposition process, for example. In the former process, dopants such as boron, aluminum, antimony, phosphorous, or arsenic may be ion-implanted into the substrate 2102 to form the S/D regions 2120. An annealing process that activates the dopants and causes them to diffuse farther into the substrate 2102 may follow the ion-implantation process. In the latter process, the substrate 2102 may first be etched to form recesses at the locations of the S/D regions 2120. An epitaxial deposition process may then be carried out to fill the recesses with material that is used to fabricate the S/D regions 2120. In some implementations, the S/D regions 2120 may be fabricated using a silicon alloy such as silicon germanium or silicon carbide. In some embodiments, the epitaxially deposited silicon alloy may be doped in situ with dopants such as boron, arsenic, or phosphorous. In some embodiments, the S/D regions 2120 may be formed using one or more alternate semiconductor materials such as germanium or a group III-V material or alloy. In further embodiments, one or more layers of metal and/or metal alloys may be used to form the S/D regions 2120.

Electrical signals, such as power and/or input/output (I/O) signals, may be routed to and/or from the devices (e.g., the transistors 2140) of the device layer 2104 through one or more interconnect layers disposed on the device layer 2104 (illustrated in FIG. 15 as interconnect layers 2106, 2108, and 2110). For example, electrically conductive features of the device layer 2104 (e.g., the gate 2122 and the S/D contacts 2124) may be electrically coupled with the interconnect structures 2128 of the interconnect layers 2106, 2108, and 2110. The one or more interconnect layers 2106, 2108, and 2110 may form a metallization stack (also referred to as an “ILD stack”) 2119 of the IC device 2100.

The interconnect structures 2128 may be arranged within the interconnect layers 2106, 2108, and 2110 to route electrical signals according to a wide variety of designs (in particular, the arrangement is not limited to the particular configuration of interconnect structures 2128 depicted in FIG. 15). Although a particular number of interconnect layers 2106, 2108, and 2110 is depicted in FIG. 15, embodiments of the present disclosure include IC devices having more or fewer interconnect layers than depicted.

In some embodiments, the interconnect structures 2128 may include lines 2128a and/or vias 2128b filled with an electrically conductive material such as a metal. The lines 2128a may be arranged to route electrical signals in a direction of a plane that is substantially parallel with a surface of the substrate 2102 upon which the device layer 2104 is formed. For example, the lines 2128a may route electrical signals in a direction in and out of the page from the perspective of FIG. 15. The vias 2128b may be arranged to route electrical signals in a direction of a plane that is substantially perpendicular to the surface of the substrate 2102 upon which the device layer 2104 is formed. In some embodiments, the vias 2128b may electrically couple lines 2128a of different interconnect layers 2106, 2108, and 2110 together.

The interconnect layers 2106, 2108, and 2110 may include an insulator material 2126 disposed between the interconnect structures 2128, as shown in FIG. 15. In some embodiments, the insulator material 2126 disposed between the interconnect structures 2128 in different ones of the interconnect layers 2106, 2108, and 2110 may have different compositions; in other embodiments, the composition of the insulator material 2126 between different interconnect layers 2106, 2108, and 2110 may be the same.

A first interconnect layer 2106 may be formed above the device layer 2104. In some embodiments, the first interconnect layer 2106 may include lines 2128a and/or vias 2128b, as shown. The lines 2128a of the first interconnect layer 2106 may be coupled with contacts (e.g., the S/D contacts 2124) of the device layer 2104.

A second interconnect layer 2108 may be formed above the first interconnect layer 2106. In some embodiments, the second interconnect layer 2108 may include vias 2128b to couple the lines 2128a of the second interconnect layer 2108 with the lines 2128a of the first interconnect layer 2106. Although the lines 2128a and the vias 2128b are structurally delineated with a line within each interconnect layer (e.g., within the second interconnect layer 2108) for the sake of clarity, the lines 2128a and the vias 2128b may be structurally and/or materially contiguous (e.g., simultaneously filled during a dual-damascene process) in some embodiments.

A third interconnect layer 2110 (and additional interconnect layers, as desired) may be formed in succession on the second interconnect layer 2108 according to similar techniques and configurations described in connection with the second interconnect layer 2108 or the first interconnect layer 2106. In some embodiments, the interconnect layers that are “higher up” in the metallization stack 2119 in the IC device 2100 (i.e., farther away from the device layer 2104) may be thicker.

The IC device 2100 may include a solder resist material 2134 (e.g., polyimide or similar material) and one or more conductive contacts 2136 formed on the interconnect layers 2106, 2108, and 2110. In FIG. 15, the conductive contacts 2136 are illustrated as taking the form of bond pads. The conductive contacts 2136 may be electrically coupled with the interconnect structures 2128 and configured to route the electrical signals of the transistor(s) 2140 to other external devices. For example, solder bonds may be formed on the one or more conductive contacts 2136 to mechanically and/or electrically couple a chip including the IC device 2100 with another component (e.g., a circuit board). The IC device 2100 may include additional or alternate structures to route the electrical signals from the interconnect layers 2106, 2108, and 2110; for example, the conductive contacts 2136 may include other analogous features (e.g., posts) that route the electrical signals to external components.

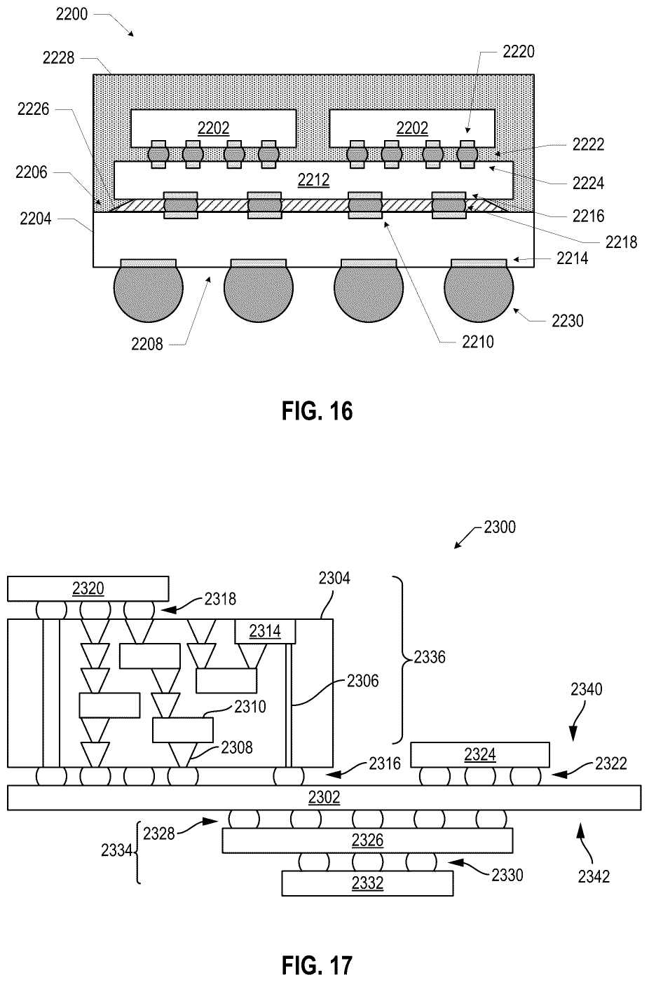

FIG. 16 is a side, cross-sectional view of an example IC package 2200 that may include one or more IC structures with transistor channel structures combining GaN and SiC (e.g., with any of the channel structures 102 described herein), in accordance with various embodiments. For example, in some embodiments, the dies 2202 may include one or more IC structures with any of the channel structures 102 described herein. In another example, in some embodiments, any of the dies 2202 of the IC package 2200 may be implemented as the die 2002 of FIG. 14. In some embodiments, the dies 2202 may include any of the embodiments of the IC device 2100. In embodiments in which the IC package 2200 includes multiple dies 2202, the IC package 2200 may be referred to as a multi-chip package (MCP). The dies 2202 may include circuitry to perform any desired functionality. For example, or more of the dies 2202 may be logic dies (e.g., silicon-based dies), and one or more of the dies 2202 may be memory dies (e.g., high bandwidth memory). In some embodiments, the IC package 2200 may be a system-in-package (SiP). In some embodiments, the IC package 2200 may include a photonics IC (PIC) co-packaged with an IC package. In some embodiments, the IC package 2200 may include fully integrated electronic photonics ICs (EPICs).

The IC package 2200 may include a package substrate 2204 may be formed of a dielectric material (e.g., a ceramic, a buildup film, an epoxy film having filler particles therein, glass, an organic material, an inorganic material, combinations of organic and inorganic materials, embedded portions formed of different materials, etc.), and may have conductive pathways extending through the dielectric material between the face 2206 and the face 2208, or between different locations on the face 2206, and/or between different locations on the face 2208. These conductive pathways may take the form of any of the interconnect structures 2128 discussed above with reference to FIG. 15.

The package substrate 2204 may include conductive contacts 2210 that are coupled to conductive pathways (not shown) through the package substrate 2204, allowing circuitry within the dies 2202 and/or the interposer 2212 to electrically couple to various ones of the conductive contacts 2214 (or to other devices included in the package substrate 2204, not shown). The IC package 2200 may include an interposer 2212 coupled to the package substrate 2204 via conductive contacts 2216 of the interposer 2212, first-level interconnects 2218, and the conductive contacts 2210 of the package substrate 2204. The first-level interconnects 2218 illustrated in FIG. 16 are solder bumps, but any suitable first-level interconnects 2218 may be used. In some embodiments, no interposer 2212 may be included in the IC package 2200; instead, the dies 2202 may be coupled directly to the conductive contacts 2210 at the face 2206 by first-level interconnects 2218. More generally, one or more dies 2202 may be coupled to the package substrate 2204 via any suitable structure (e.g., a silicon bridge, an organic bridge, one or more waveguides, one or more interposers, wirebonds, etc.).

The IC package 2200 may include one or more dies 2202 coupled to the interposer 2212 via conductive contacts 2220 of the dies 2202, first-level interconnects 2222, and conductive contacts 2224 of the interposer 2212. The conductive contacts 2224 may be coupled to conductive pathways (not shown) through the interposer 2212, allowing circuitry within the dies 2202 to electrically couple to various ones of the conductive contacts 2216 (or to other devices included in the interposer 2212, not shown). The first-level interconnects 2222 illustrated in FIG. 16 are solder bumps, but any suitable first-level interconnects 2222 may be used. For example, the first-level interconnects 2222 may include hybrid bonding interconnects. As used herein, a “conductive contact” may refer to a portion of conductive material (e.g., metal) serving as an interface between different components; conductive contacts may be recessed in, flush with, or extending away from a surface of a component, and may take any suitable form (e.g., a conductive pad or socket).

In some embodiments, an underfill material 2226 may be disposed between the package substrate 2204 and the interposer 2212 around the first-level interconnects 2218, and a mold compound 2228 may be disposed around the dies 2202 and the interposer 2212 and in contact with the package substrate 2204. In some embodiments, the underfill material 2226 may be the same as the mold compound 2228. Example materials that may be used for the underfill material 2226 and the mold compound 2228 are epoxy mold materials, as suitable. Second-level interconnects 2230 may be coupled to the conductive contacts 2214. The second-level interconnects 2230 illustrated in FIG. 16 are solder balls (e.g., for a ball grid array arrangement), but any suitable second-level interconnects 2230 may be used (e.g., pins in a pin grid array arrangement or lands in a land grid array arrangement). The second-level interconnects 2230 may be used to couple the IC package 2200 to another component, such as a circuit board (e.g., a motherboard), an interposer, or another IC package, as known in the art and as discussed below with reference to FIG. 17.

Although the IC package 2200 illustrated in FIG. 16 is a flip chip package, other package architectures may be used. For example, the IC package 2200 may be a ball grid array (BGA) package, such as an embedded wafer-level ball grid array (eWLB) package. In another example, the IC package 2200 may be a wafer-level chip scale package (WLCSP) or a panel fanout (FO) package. Although two dies 2202 are illustrated in the IC package 2200 of FIG. 16, an IC package 2200 may include any desired number of dies 2202. An IC package 2200 may include additional passive components, such as surface-mount resistors, capacitors, and inductors disposed on the first face 2206 or the second face 2208 of the package substrate 2204, or on either face of the interposer 2212. More generally, an IC package 2200 may include any other active or passive components known in the art.

FIG. 17 is a side, cross-sectional view of an IC device assembly 2300 that may include one or more IC packages or other electronic components (e.g., a die) including one or more IC structures with transistor channel structures combining GaN and SiC (e.g., with any of the channel structures 102 described herein) in accordance with any of the embodiments disclosed herein. The IC device assembly 2300 includes a number of components disposed on a circuit board 2302 (which may be, e.g., a motherboard). The IC device assembly 2300 includes components disposed on a first face 2340 of the circuit board 2302 and an opposing second face 2342 of the circuit board 2302; generally, components may be disposed on one or both faces 2340 and 2342. Any of the IC packages discussed below with reference to the IC device assembly 2300 may take the form of any of the embodiments of the IC package 2200 discussed above with reference to FIG. 16.

In some embodiments, the circuit board 2302 may be a PCB including multiple metal layers separated from one another by layers of dielectric material and interconnected by electrically conductive vias. Any one or more of the metal layers may be formed in a desired circuit pattern to route electrical signals (optionally in conjunction with other metal layers) between the components coupled to the circuit board 2302. In other embodiments, the circuit board 2302 may be a non-PCB substrate.

The IC device assembly 2300 illustrated in FIG. 17 includes a package-on-interposer structure 2336 coupled to the first face 2340 of the circuit board 2302 by coupling components 2316. The coupling components 2316 may electrically and mechanically couple the package-on-interposer structure 2336 to the circuit board 2302 and may include solder balls (as shown in FIG. 17), male and female portions of a socket, an adhesive, an underfill material, and/or any other suitable electrical and/or mechanical coupling structure.

The package-on-interposer structure 2336 may include an IC package 2320 coupled to a package interposer 2304 by coupling components 2318. The coupling components 2318 may take any suitable form for the application, such as the forms discussed above with reference to the coupling components 2316. Although a single IC package 2320 is shown in FIG. 17, multiple IC packages may be coupled to the package interposer 2304; indeed, additional interposers may be coupled to the package interposer 2304. The package interposer 2304 may provide an intervening substrate used to bridge the circuit board 2302 and the IC package 2320. The IC package 2320 may be or include, for example, a die (the die 2002 of FIG. 14), an IC device (e.g., the IC device 2100 of FIG. 15), or any other suitable component. Generally, the package interposer 2304 may spread a connection to a wider pitch or reroute a connection to a different connection. For example, the package interposer 2304 may couple the IC package 2320 (e.g., a die) to a set of BGA conductive contacts of the coupling components 2316 for coupling to the circuit board 2302. In the embodiment illustrated in FIG. 17, the IC package 2320 and the circuit board 2302 are attached to opposing sides of the package interposer 2304; in other embodiments, the IC package 2320 and the circuit board 2302 may be attached to a same side of the package interposer 2304. In some embodiments, three or more components may be interconnected by way of the package interposer 2304.

In some embodiments, the package interposer 2304 may be formed as a PCB, including multiple metal layers separated from one another by layers of dielectric material and interconnected by electrically conductive vias. In some embodiments, the package interposer 2304 may be formed of an epoxy resin, a fiberglass-reinforced epoxy resin, an epoxy resin with inorganic fillers, a ceramic material, or a polymer material such as polyimide. In some embodiments, the package interposer 2304 may be formed of alternate rigid or flexible materials that may include the same materials described above for use in a semiconductor substrate, such as silicon, germanium, and other group III-V and group IV materials. The package interposer 2304 may include metal lines 2310 and vias 2308, including but not limited to through-silicon vias (TSVs) 2306. The package interposer 2304 may further include embedded devices 2314, including both passive and active devices. Such devices may include, but are not limited to, capacitors, decoupling capacitors, resistors, inductors, fuses, diodes, transformers, sensors, electrostatic discharge (ESD) devices, and memory devices. More complex devices such as radio frequency devices, power amplifiers, power management devices, antennas, arrays, sensors, and microelectromechanical systems (MEMS) devices may also be formed on the package interposer 2304. The package-on-interposer structure 2336 may take the form of any of the package-on-interposer structures known in the art. In some embodiments, the package interposer 2304 may include one or more transistors with any of the channel structures 102 described herein.

The IC device assembly 2300 may include an IC package 2324 coupled to the first face 2340 of the circuit board 2302 by coupling components 2322. The coupling components 2322 may take the form of any of the embodiments discussed above with reference to the coupling components 2316, and the IC package 2324 may take the form of any of the embodiments discussed above with reference to the IC package 2320.

The IC device assembly 2300 illustrated in FIG. 17 includes a package-on-package structure 2334 coupled to the second face 2342 of the circuit board 2302 by coupling components 2328. The package-on-package structure 2334 may include an IC package 2326 and an IC package 2332 coupled together by coupling components 2330 such that the IC package 2326 is disposed between the circuit board 2302 and the IC package 2332. The coupling components 2328 and 2330 may take the form of any of the embodiments of the coupling components 2316 discussed above, and the IC packages 2326 and 2332 may take the form of any of the embodiments of the IC package 2320 discussed above. The package-on-package structure 2334 may be configured in accordance with any of the package-on-package structures known in the art.

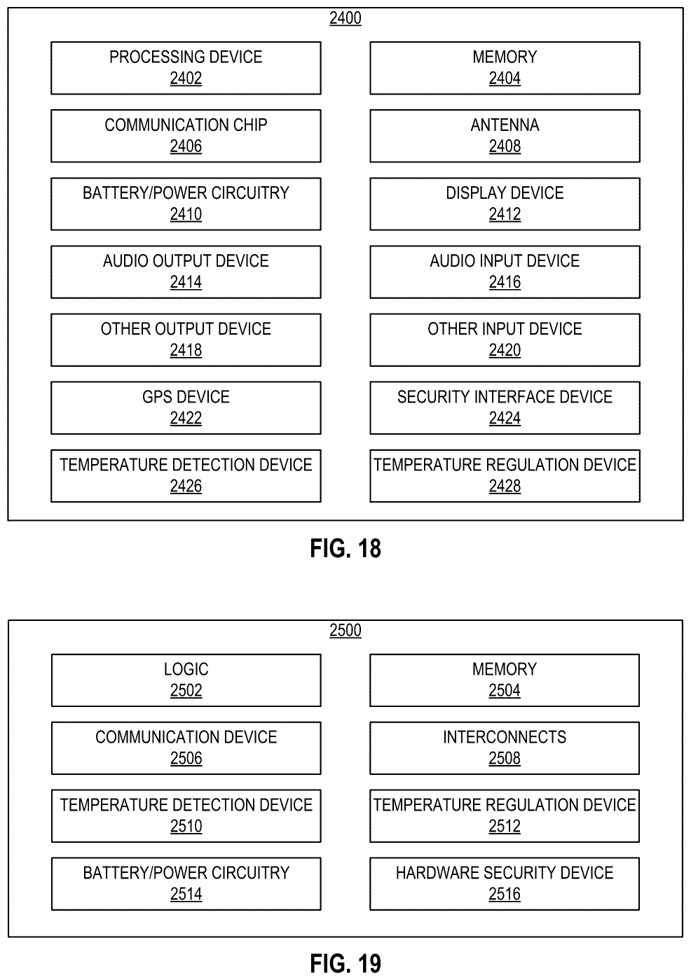

FIG. 18 is a block diagram of an example computing device 2400 that may include one or more components including IC structures with transistor channel structures combining GaN and SiC (e.g., with any of the channel structures 102 described herein) in accordance with any of the embodiments disclosed herein. For example, any suitable ones of the components of the computing device 2400 may include a die (e.g., the die 2002 of FIG. 14) having one or more IC structures with any of the channel structures 102 as described herein. Any one or more of the components of the computing device 2400 may include an IC device 2100 of FIG. 15, an IC package 2200 of FIG. 16, or an IC device assembly 2300 of FIG. 17.

A number of components are illustrated in FIG. 18 as included in the computing device 2400, but any one or more of these components may be omitted or duplicated, as suitable for the application. In some embodiments, some or all of the components included in the computing device 2400 may be attached to one or more motherboards. In some embodiments, some or all of these components are fabricated onto a single system-on-chip (SoC) die.

Additionally, in various embodiments, the computing device 2400 may not include one or more of the components illustrated in FIG. 18, but the computing device 2400 may include interface circuitry for coupling to the one or more components. For example, the computing device 2400 may not include a display device 2412, but may include display device interface circuitry (e.g., a connector and driver circuitry) to which a display device 2412 may be coupled. In another set of examples, the computing device 2400 may not include an audio input device 2416 or an audio output device 2414 but may include audio input or output device interface circuitry (e.g., connectors and supporting circuitry) to which an audio input device 2416 or audio output device 2414 may be coupled.

The computing device 2400 may include a processing device 2402 (e.g., one or more processing devices). As used herein, the term “processing device” or “processor” may refer to any device or portion of a device that processes electronic data from registers and/or memory to transform that electronic data into other electronic data that may be stored in registers and/or memory. The processing device 2402 may include one or more digital signal processors (DSPs), application-specific integrated circuits (ASICs), central processing units (CPUs), graphics processing units (GPUs), cryptoprocessors (specialized processors that execute cryptographic algorithms within hardware), server processors, or any other suitable processing devices. In some embodiments, the processing device 2402 may include one or more transistors with any of the channel structures 102 described herein

The computing device 2400 may include a memory 2404, which may itself include one or more memory devices such as volatile memory (e.g., DRAM), non-volatile memory (e.g., read-only memory (ROM)), flash memory, solid state memory, and/or a hard drive. In some embodiments, the memory 2404 may include memory that shares a die with the processing device 2402. This memory may be used as cache memory and may include embedded DRAM (eDRAM) or spin transfer torque MRAM. In some embodiments, the memory 2404 may include one or more transistors with any of the channel structures 102 as described herein.

In some embodiments, the computing device 2400 may include a communication chip 2406 (e.g., one or more communication chips). For example, the communication chip 2406 may be configured for managing wireless communications for the transfer of data to and from the computing device 2400. The term “wireless” and its derivatives may be used to describe circuits, devices, systems, methods, techniques, communications channels, etc., that may communicate data through the use of modulated electromagnetic radiation through a nonsolid medium. The term does not imply that the associated devices do not contain any wires, although in some embodiments they might not.

The communication chip 2406 may implement any of a number of wireless standards or protocols, including but not limited to Institute for Electrical and Electronic Engineers (IEEE) standards including Wi-Fi (IEEE 1402.11 family), IEEE 1402.16 standards (e.g., IEEE 1402.16-2005 Amendment), Long-Term Evolution (LTE) project along with any amendments, updates, and/or revisions (e.g., advanced LTE project, ultramobile broadband (UMB) project (also referred to as “3GPP2”), etc.). IEEE 1402.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 1402.16 standards. The communication chip 2406 may operate in accordance with a Global System for Mobile Communication (GSM), General Packet Radio Service (GPRS), Universal Mobile Telecommunications System (UMTS), High-Speed Packet Access (HSPA), Evolved HSPA (E-HSPA), or LTE network. The communication chip 2406 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication chip 2406 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. The communication chip 2406 may operate in accordance with other wireless protocols in other embodiments. The computing device 2400 may include an antenna 2408 to facilitate wireless communications and/or to receive other wireless communications (such as AM or FM radio transmissions).

In some embodiments, the communication chip 2406 may manage wired communications, such as electrical, optical, or any other suitable communication protocols (e.g., the Ethernet). As noted above, the communication chip 2406 may include multiple communication chips. For instance, a first communication chip 2406 may be dedicated to shorter-range wireless communications such as Wi-Fi or Bluetooth, and a second communication chip 2406 may be dedicated to longer-range wireless communications such as global positioning system (GPS), EDGE, GPRS, CDMA, WiMAX, LTE, EV-DO, or others. In some embodiments, a first communication chip 2406 may be dedicated to wireless communications, and a second communication chip 2406 may be dedicated to wired communications.

The computing device 2400 may include a battery/power circuitry 2410. The battery/power circuitry 2410 may include one or more energy storage devices (e.g., batteries or capacitors) and/or circuitry for coupling components of the computing device 2400 to an energy source separate from the computing device 2400 (e.g., AC line power).

The computing device 2400 may include a display device 2412 (or corresponding interface circuitry, as discussed above). The display device 2412 may include any visual indicators, such as a heads-up display, a computer monitor, a projector, a touchscreen display, a liquid crystal display (LCD), a light-emitting diode display, or a flat panel display, for example.

The computing device 2400 may include an audio output device 2414 (or corresponding interface circuitry, as discussed above). The audio output device 2414 may include any device that generates an audible indicator, such as speakers, headsets, or earbuds, for example.

The computing device 2400 may include an audio input device 2416 (or corresponding interface circuitry, as discussed above). The audio input device 2416 may include any device that generates a signal representative of a sound, such as microphones, microphone arrays, or digital instruments (e.g., instruments having a musical instrument digital interface (MIDI) output).

The computing device 2400 may include an other output device 2418 (or corresponding interface circuitry, as discussed above). Examples of the other output device 2418 may include an audio codec, a video codec, a printer, a wired or wireless transmitter for providing information to other devices, or an additional storage device.

The computing device 2400 may include an other input device 2420 (or corresponding interface circuitry, as discussed above). Examples of the other input device 2420 may include an accelerometer, a gyroscope, a compass, an image capture device, a keyboard, a cursor control device such as a mouse, a stylus, a touchpad, a bar code reader, a Quick Response (QR) code reader, any sensor, or a radio frequency identification (RFID) reader.

The computing device 2400 may include a GPS device 2422 (or corresponding interface circuitry, as discussed above). The GPS device 2422 may be in communication with a satellite-based system and may receive a location of the computing device 2400, as known in the art.

The computing device 2400 may include a security interface device 2424. The security interface device 2424 may include any device that provides security features for the computing device 2400 or for any individual components therein (e.g., for the processing device 2402 or for the memory 2404). Examples of security features may include authorization, access to digital certificates, access to items in keychains, etc. Examples of the security interface device 2424 may include a software firewall, a hardware firewall, an antivirus, a content filtering device, or an intrusion detection device.

In some embodiments, the computing device 2400 may include a temperature detection device 2426 and a temperature regulation device 2428.

The temperature detection device 2426 may include any device capable of determining temperatures of the computing device 2400 or of any individual components therein (e.g., temperatures of the processing device 2402 or of the memory 2404). In various embodiments, the temperature detection device 2426 may be configured to determine temperatures of an object (e.g., the computing device 2400, components of the computing device 2400, devices coupled to the computing device, etc.), temperatures of an environment (e.g., a data center that includes, is controlled by, or otherwise associated with the computing device 2400), and so on. The temperature detection device 2426 may include one or more temperature sensors. Different temperature sensors of the temperature detection device 2426 may have different locations within and around the computing device 2400. A temperature sensor may generate data (e.g., digital data) representing detected temperatures and provide the data to another device, e.g., to the temperature regulation device 2428, the processing device 2402, the memory 2404, etc. In some embodiments, a temperature sensor of the temperature detection device 2426 may be turned on or off, e.g., by the processing device 2402 or an external system. The temperature sensor detects temperatures when it is on and does not detect temperatures when it is off. In other embodiments, a temperature sensor of the temperature detection device 2426 may detect temperatures continuously and automatically or detect temperatures at predefined times or at times triggered by an event associated with the computing device 2400 or any components therein.

The temperature regulation device 2428 may include any device configured to change (e.g., decrease) temperatures, e.g., based on one or more target temperatures and/or based on temperature measurements performed by the temperature detection device 2426. A target temperature may be a preferred temperature. A target temperature may depend on a setting in which the computing device 2400 operates. In some embodiments, the target temperature may be 200 Kelvin degrees or lower. In some embodiments, the target temperature may be 20 Kelvin degrees or lower, or 5 Kelvin degrees or lower. Target temperatures for different objects and different environments of, or associated with, the computing device 2400 can be different. In some embodiments, cooling provided by the temperature regulation device 2428 may be a multi-stage process with temperatures ranging from room temperature to 4K or lower.

In some embodiments, the temperature regulation device 2428 may include one or more cooling devices. Different cooling device may have different locations within and around the computing device 2400. A cooling device of the temperature regulation device 2428 may be associated with one or more temperature sensors of the temperature detection device 2426 and may be configured to operate based on temperatures detected the temperature sensors. For instance, a cooling device may be configured to determine whether a detected ambient temperature is above the target temperature or whether the detected ambient temperature is higher than the target temperature by a predetermined value or determine whether any other temperature-related condition associated with the temperature of the computing device 2400 is satisfied. In response to determining that one or more temperature-related condition associated with the temperature of the computing device 2400 are satisfied (e.g., in response to determining that the detected ambient temperature is above the target temperature), a cooling device may trigger its cooling mechanism and start to decrease the ambient temperature. Otherwise, the cooling device does not trigger any cooling. A cooling device of the temperature regulation device 2428 may operate with various cooling mechanisms, such as evaporation cooling, radiation cooling, conduction cooling, convection cooling, other cooling mechanisms, or any combination thereof. A cooling device of the temperature regulation device 2428 may include a cooling agent, such as a water, oil, liquid nitrogen, liquid helium, etc. In some embodiments, the temperature regulation device 2428 may be, for example, a dilution refrigerator, a helium-3 refrigerator, or a liquid helium refrigerator. In some embodiments, the temperature regulation device 2428 or any portions thereof (e.g., one or more of the individual cooling devices) may be connected to the computing device 2400 in close proximity (e.g., less than about 1 meter) or may be provided in a separate enclosure where a dedicated heat exchanger (e.g., a compressor, a heating, ventilation, and air conditioning (HVAC) system, liquid helium, liquid nitrogen, etc.) may reside.

By maintaining the target temperatures, the energy consumption of the computing device 2400 (or components thereof) can be reduced, while the computing efficiency may be improved. For example, when the computing device 2400 (or components thereof) operates at lower temperatures, energy dissipation (e.g., heat dissipation) may be reduced. Further, energy consumed by semiconductor components (e.g., energy needed for switching transistors of any of the components of the computing device 2400) can also be reduced. Various semiconductor materials may have lower resistivity and/or higher mobility at lower temperatures. That way, the electrical current per unit supply voltage may be increased by lowering temperatures. Conversely, for the same current that would be needed, the supply voltage may be lowered by lowering temperatures. As energy corelates to the supply voltage, the energy consumption of the semiconductor components may lower too. In some implementations, the energy savings due to reducing heat dissipation and reducing energy consumed by semiconductor components of the computing device or components thereof may outweigh (sometimes significantly outweigh) the costs associated with energy needed for cooling.

The computing device 2400 may have any desired form factor, such as a handheld or mobile computing device (e.g., a cell phone, a smart phone, a mobile internet device, a music player, a tablet computer, a laptop computer, a netbook computer, an ultrabook computer, a personal digital assistant (PDA), an ultramobile personal computer, etc.), a desktop computing device, a server or other networked computing component, a printer, a scanner, a monitor, a set-top box, an entertainment control unit, a vehicle control unit, a digital camera, a digital video recorder, or a wearable computing device. In some embodiments, the computing device 2400 may be any other electronic device that processes data.

FIG. 19 is a block diagram of an example processing device 2500 that may include one or more components including IC structures with transistor channel structures combining GaN and SiC (e.g., with any of the channel structures 102 described herein) as described herein. For example, any suitable ones of the components of the processing device 2500 may include a die (e.g., the die 2002 of FIG. 14) having one or more IC structures with any of the channel structures 102 as described herein. Any one or more of the components of the processing device 2500 may include an IC device 2100 of FIG. 15, an IC package 2200 of FIG. 16, or an IC device assembly 2300 of FIG. 17. Any one or more of the components of the processing device 2500 may include, or be included in, a computing device 2400 of FIG. 18; for example, the processing device 2500 may be the processing device 2402 of the computing device 2400.

A number of components are illustrated in FIG. 19 as included in the processing device 2500, but any one or more of these components may be omitted or duplicated, as suitable for the application. In some embodiments, some or all of the components included in the processing device 2500 may be attached to one or more motherboards. In some embodiments, some or all of these components are fabricated on a single SoC die or coupled to a single support structure, e.g., to a single carrier substrate.

Additionally, in various embodiments, the processing device 2500 may not include one or more of the components illustrated in FIG. 19, but the processing device 2500 may include interface circuitry for coupling to the one or more components. For example, the processing device 2500 may not include a memory 2504, but may include display device interface circuitry (e.g., a connector and driver circuitry) to which a memory 2504 may be coupled.

The processing device 2500 may include logic circuitry 2502 (e.g., one or more circuits configured to implement logic/compute functionality). Examples of such circuits include ICs implementing one or more of input/output (I/O) functions, arithmetic operations, pipelining of data, etc.

In some embodiments, the logic circuitry 2502 may include one or more circuits responsible for read/write operations with respect to the data stored in the memory 2504. To that end, the logic circuitry 2502 may include one or more I/O ICs configured to control access to data stored in the memory 2504.

In some embodiments, the logic circuitry 2502 may include one or more high-performance compute dies, configured to perform various operations with respect to data stored in the memory 2504 (e.g., arithmetic and logic operations, pipelining of data from one or more memory dies of the memory 2504, and possibly also data from external devices/chips). In some embodiments, the logic circuitry 2502 may be configured to only control I/O access to data but not perform any operations on the data. In some embodiments, the logic circuitry 2502 may implement ICs configured to implement I/O control of data stored in the memory 2504, assemble data from the memory 2504 for transport (e.g., transport over a central bus) to devices/chips that are either internal or external to the processing device 2500, etc. In some embodiments, the logic circuitry 2502 may not be configured to perform any operations on the data besides I/O and assembling for transport to the memory 2504. In some embodiments, the logic circuitry 2502 may include one or more transistors with any of the channel structures 102 described herein.

The processing device 2500 may include a memory 2504, which may include one or more ICs configure to implement memory circuitry (e.g., ICs implementing one or more of memory devices, memory arrays, control logic configured to control the memory devices and arrays, etc.). In some embodiments, the memory 2504 may be implemented substantially as described above with reference to the memory 2404 (FIG. 18). In some embodiments, the memory 2504 may be a designated device configured to provide storage functionality for the components of the processing device 2500 (e.g., local), while the memory 2404 may be configured to provide system-level storage functionality for the entire computing device 2400 (e.g., global). In some embodiments, the memory 2504 may include memory that shares a die with the logic circuitry 2502. In some embodiments, the memory 2504 may include one or more memory cells with transistors implementing any of the channel structures 102 described herein.

The processing device 2500 may include a communication device 2506, which may be implemented substantially as described above with reference to the communication chip 2406 (FIG. 18). In some embodiments, the communication device 2506 may be a designated device configured to provide communication functionality for the components of the processing device 2500 (e.g., local), while the communication chip 2406 may be configured to provide system-level communication functionality for the entire computing device 2400 (e.g., global).

The processing device 2500 may include interconnects 2508, which may include any element or device that includes an electrically conductive material for providing electrical connectivity to one or more components of, or associated with, a processing device 2500 or/and between various such components. Examples of the interconnects 2508 include conductive lines/wires (also sometimes referred to as “lines” or “metal lines” or “trenches”) and conductive vias (also sometimes referred to as “vias” or “metal vias”). In some embodiments, the interconnects 2508 may be implemented as the interconnect structures 2128 of FIG. 15, described above.

The processing device 2500 may include a temperature detection device 2510 which may be implemented substantially as described above with reference to the temperature detection device 2426 of FIG. 18 but configured to determine temperatures on a more local scale, e.g., of the processing device 2500 of components thereof. In some embodiments, the temperature detection device 2510 may be a designated device configured to provide temperature detection functionality for the components of the processing device 2500 (e.g., local), while the temperature detection device 2426 may be configured to provide system-level temperature detection functionality for the entire computing device 2400 (e.g., global).

The processing device 2500 may include a temperature regulation device 2512 which may be implemented substantially as described above with reference to the temperature regulation device 2428 of FIG. 18 but configured to regulate temperatures on a more local scale, e.g., of the processing device 2500 of components thereof. In some embodiments, the temperature regulation device 2512 may be a designated device configured to provide temperature regulation functionality for the components of the processing device 2500 (e.g., local), while the temperature regulation device 2428 may be configured to provide system-level temperature regulation functionality for the entire computing device 2400 (e.g., global).

The processing device 2500 may include a battery/power circuitry 2514 which may be implemented substantially as described above with reference to the battery/power circuitry 2410 of FIG. 18. In some embodiments, the battery/power circuitry 2514 may be a designated device configured to provide battery/power functionality for the components of the processing device 2500 (e.g., local), while the battery/power circuitry 2410 may be configured to provide system-level battery/power functionality for the entire computing device 2400 (e.g., global).

The processing device 2500 may include a hardware security device 2516 which may be implemented substantially as described above with reference to the security interface device 2424 of FIG. 18. In some embodiments, the hardware security device 2516 may be a physical computing device configured to safeguard and manage digital keys, perform encryption and decryption functions for digital signatures, authentication, and other cryptographic functions. In some embodiments, the hardware security device 2516 may include one or more secure cryptoprocessors chips.

The following paragraphs provide examples of various ones of the embodiments disclosed herein.

Example 1 provides a transistor, including a gate electrode material; a gate insulator material; and a channel structure, in which the gate insulator material is between the channel structure and the gate electrode material, and the channel structure includes a first portion, a second portion (separate from the first portion), and a third portion (separate from the first and second portions), and in which: the second portion is between the first portion and the third portion, and either (1) the first portion and the third portion include gallium and nitrogen (e.g., in the form of GaN), and the second portion includes silicon and carbon (e.g., in the form of SiC), or (2) the first portion and the third portion include silicon and carbon (e.g., in the form of SiC), and the second portion includes gallium and nitrogen (e.g., in the form of GaN).

Example 2 provides the transistor according to example 1, in which, along a direction of a gate length of the transistor, the second portion is adjacent to (e.g., side by side with) the first portion, and the third portion is adjacent to (e.g., side by side with) the second portion.

Example 3 provides the transistor according to example 2, in which, in the direction, a dimension of the first portion or a dimension of the third portion is between about 10% and about 80% of a dimension of the second portion.

Example 4 provides the transistor according to example 3, in which, in the direction, the dimension of the first portion is substantially equal to the dimension of the third portion.

Example 5 provides the transistor according to example 3, in which, in the direction, the dimension of the first portion is smaller than the dimension of the third portion.

Example 6 provides the transistor according to example 3, in which, in the direction, the dimension of the first portion is larger than the dimension of the third portion.

Example 7 provides the transistor according to any one of examples 2-6, e.g., according to claim 2, in which, in planes perpendicular to the direction, a dimension of the first portion is substantially equal to a dimension of the third portion.

Example 8 provides the transistor according to example 7, in which, in the planes perpendicular to the direction, the dimension of the first portion is different from a dimension of the second portion.

Example 9 provides the transistor according to any one of examples 2-6, e.g., according to claim 2, in which, in planes perpendicular to the direction, a dimension of the first portion is smaller than a dimension of the third portion.

Example 10 provides the transistor according to example 1, in which, in a plane substantially perpendicular to the gate length of the transistor, the second portion is stacked above (e.g., vertically stacked) the first portion and the third portion is stacked above (e.g., vertically stacked) the second portion.

Example 11 provides the transistor according to example 10, in which a thickness of the second portion is at least about 50% larger than a thickness of the first portion or a thickness of the second portion.

Example 12 provides the transistor according to example 11, in which the thickness of the first portion is substantially equal to the thickness of the third portion.

Example 13 provides the transistor according to example 11, in which the thickness of the first portion is smaller than the thickness of the third portion.

Example 14 provides the transistor according to example 11, in which the thickness of the first portion is larger than the thickness of the third portion.

Example 15 provides the transistor according to any one of examples 11-14, in which a sum of the thickness of the first portion, the thickness of the second portion, and the thickness of the second portion is between about 5 nanometers and about 100 nanometers.

Example 16 provides the transistor according to any one of the preceding examples, in which (1) the channel structure is shaped as a fin, and the gate insulator material wraps around the fin, or (2) the channel structure is shaped as a wire, and the gate insulator material wraps around the wire.

Example 17 provides an integrated circuit (IC) structure, including a transistor; and a conductive structure coupled to the transistor, in which the transistor includes a gate electrode, a gate insulator, and a channel structure, in which the gate insulator is between the channel structure and the gate electrode, the channel structure includes a first portion including gallium and nitrogen, and the channel structure further includes a second portion (separate from the first portion) including silicon and carbon.

Example 18 provides the IC structure according to example 17, in which the channel structure further includes a third portion (separate from the first and second portions), and in which (1) the third portion includes gallium and nitrogen, and the second portion is between the first portion and the third portion, or (2) the third portion includes silicon and carbon, and the first portion is between the second portion and the third portion.

Example 19 provides an integrated circuit (IC) package, including an IC die, including a transistor; and a further component, coupled to the IC die, in which a channel region of the transistor includes a first portion and a second portion in contact with the first portion, the first portion includes a semiconductor material including gallium and nitrogen, and the second portion includes a semiconductor material including silicon and carbon.

Example 20 provides the IC package according to example 19, in which the further component is one of a package substrate, an interposer, or a further IC die.

Example 21 provides the IC package according to examples 19 or 20, in which, along the second portion is in a single layer with the first portion.

Example 22 provides the IC package according to examples 19 or 20, in which, in a plane substantially perpendicular to the gate length of the transistor, the second portion is stacked above (e.g., vertically stacked) the first portion.

Example 23 provides the IC package according to any one of examples 19-22, further

including an insulator material around at least a portion of the IC die.

Example 24 provides the IC package according to any one of examples 19-23, further including interconnects between the further component and the IC die.

Example 25 provides the IC package according to example 24, in which the interconnects are solder bumps.

Example 26 provides the IC package according to example 24, in which the interconnects are hybrid bonding interconnects.

Example 27 provides the IC package according to any one of examples 24-26, further including first conductive contacts at a surface of the further component closest to the IC die; and second conductive contacts at a surface of the IC die closest to the further component, in which the interconnects are between the first conductive contacts and the second conductive contacts.

Example 28 provides the IC package according to example 27, in which at least one of the first conductive contacts or the second conductive contacts includes a conductive pad.

Example 29 provides the IC package according to example 27, in which at least one of the first conductive contacts or the second conductive contacts includes a conductive socket.

Example 30 provides the IC package according to any one of examples 19-29, in which: the further component is an interposer, the IC package further includes a package substrate coupled to the interposer, the IC die is coupled to a first face of the interposer, and the package substrate is coupled to a second face of the interposer opposite the first face of the interposer.

Example 31 provides the IC package according to example 30, further including interconnects between the interposer and the package substrate.

Example 32 provides the IC package according to example 31, further including an underfill material around the interconnects.

Example 33 provides an electronic device, including a carrier substrate; and one or more of the transistors or IC structures according to any one of the preceding examples and/or the IC package according to any one of the preceding claims, coupled to the carrier substrate.

Example 34 provides the electronic device according to example 33, in which the carrier substrate is a motherboard.

Example 35 provides the electronic device according to example 33, in which the carrier substrate is a PCB.

Example 36 provides the electronic device according to any one of examples 33-35, in which the electronic device is a wearable electronic device (e.g., a smart watch) or handheld electronic device (e.g., a mobile phone).

Example 37 provides the electronic device according to any one of examples 33-36, in which the electronic device further includes one or more communication chips and an antenna.

Example 38 provides the electronic device according to any one of examples 33-37, in which the electronic device is memory device.

Example 39 provides the electronic device according to any one of examples 33-37, in which the electronic device is one of an RF transceiver, a switch, a power amplifier, a low-noise amplifier, a filter, a filter bank, a duplexer, an upconverter, or a downconverter of an RF communications device, e.g., of an RF transceiver.

Example 40 provides the electronic device according to any one of examples 33-37, in which the electronic device is a computing device.

Example 41 provides the electronic device according to any one of examples 33-40, in which the electronic device is included in a base station of a wireless communication system.

Example 42 provides the electronic device according to any one of examples 33-40, in which the electronic device is included in a user equipment device (i.e., a mobile device) of a wireless communication system.

The above description of illustrated implementations of the disclosure, including what is described in the Abstract, is not intended to be exhaustive or to limit the disclosure to the precise forms disclosed. While specific implementations of, and examples for, the disclosure are described herein for illustrative purposes, various equivalent modifications are possible within the scope of the disclosure, as those skilled in the relevant art will recognize. These modifications may be made to the disclosure in light of the above detailed description.

1. A transistor, comprising:
a gate electrode material;
a gate insulator material; and
a channel structure, wherein the gate insulator material is between the channel structure and the gate electrode material, and the channel structure includes a first portion, a second portion, and a third portion, and
wherein:
the second portion is between the first portion and the third portion, and
(1) the first portion and the third portion include gallium and nitrogen, and the second portion includes silicon and carbon, or
(2) the first portion and the third portion include silicon and, and the second portion includes gallium and nitrogen.

2. The transistor according to claim 1, wherein, along a direction of a gate length of the transistor, the second portion is adjacent to the first portion, and the third portion is adjacent to the second portion.

3. The transistor according to claim 2, wherein, in the direction, a dimension of the first portion or a dimension of the third portion is between about 10% and about 80% of a dimension of the second portion.

4. The transistor according to claim 3, wherein, in the direction, the dimension of the first portion is substantially equal to the dimension of the third portion.

5. The transistor according to claim 3, wherein, in the direction, the dimension of the first portion is smaller than the dimension of the third portion.

6. The transistor according to claim 3, wherein, in the direction, the dimension of the first portion is larger than the dimension of the third portion.

7. The transistor according to claim 2, wherein, in planes perpendicular to the direction, a dimension of the first portion is substantially equal to a dimension of the third portion.

8. The transistor according to claim 7, wherein, in the planes perpendicular to the direction, the dimension of the first portion is different from a dimension of the second portion.

9. The transistor according to claim 2, wherein, in planes perpendicular to the direction, a dimension of the first portion is smaller than a dimension of the third portion.

10. The transistor according to claim 1, wherein the second portion is stacked above the first portion and the third portion is stacked above the second portion.

11. The transistor according to claim 10, wherein a thickness of the second portion is at least about 50% larger than a thickness of the first portion or a thickness of the second portion.

12. The transistor according to claim 11, wherein the thickness of the first portion is substantially equal to the thickness of the third portion.

13. The transistor according to claim 11, wherein the thickness of the first portion is smaller than the thickness of the third portion.

14. The transistor according to claim 11, wherein the thickness of the first portion is larger than the thickness of the third portion.

15. The transistor according to claim 11, wherein a sum of the thickness of the first portion, the thickness of the second portion, and the thickness of the second portion is between about 5 nanometers and about 100 nanometers.

16. The transistor according to claim 1, wherein (1) the channel structure is shaped as a fin, and the gate insulator material wraps around the fin, or (2) the channel structure is shaped as a wire, and the gate insulator material wraps around the wire.

17. An integrated circuit (IC) structure, comprising:
a transistor; and
a conductive structure coupled to the transistor,
wherein the transistor includes:
a gate electrode,
a gate insulator, and
a channel structure, wherein the gate insulator is between the channel structure and the gate electrode, the channel structure includes a first portion comprising gallium and nitrogen, and the channel structure further includes a second portion comprising silicon and carbon.

18. The IC structure according to claim 17, wherein the channel structure further includes a third portion, and wherein (1) the third portion includes gallium and nitrogen, and the second portion is between the first portion and the third portion, or (2) the third portion includes silicon and carbon, and the first portion is between the second portion and the third portion.

19. An integrated circuit (IC) package, comprising:
an IC die, comprising a transistor; and
a further component, coupled to the IC die,
wherein a channel region of the transistor includes a first portion and a second portion in contact with the first portion, the first portion includes a semiconductor material comprising gallium and nitrogen, and the second portion includes a semiconductor material comprising silicon and carbon.

20. The IC package according to claim 19, wherein the further component is one of a package substrate, an interposer, or a further IC die.
